(19) United States
(12) Patent Application Publication
(10) Pub. No.: US 2026/0219297 A1
(43) Pub. Date: Jul. 30, 2026

(54) TESTING CONNECTOR

(71) Applicant: ISC CO., LTD, Gyeonggi-do (KR)

(72) Inventors: Dong Gyun WOO, Gyeonggi-do (KR); Sang Hyun JOO, Gyeonggi-do (KR); Jun Hyuk YANG, Gyeonggi-do (KR); Gi Soo EUM, Gyeonggi-do (KR); Ji Young HONG, Gyeonggi-do (KR); Woong MYUNG, Gyeonggi-do (KR)

(21) Appl. No.: 19/148,419

(22) PCT Filed: Feb. 6, 2024
(86) PCT No.: PCT/KR2024/001695

§ 371 Date: Jul. 16, 2025

(30) Foreign Application Priority Data
Feb. 10, 2023 (KR) 10-2023-0018054
Feb. 2, 2024 (KR) 10-2024-0016356

(51) Int. Cl. G01R 1/04; G01R 1/073

(52) U.S. Cl. CPC G01R 1/0416; G01R 1/07321; G01R 1/07328; G01R 1/07364

(57) ABSTRACT

A testing connector disposed between a test apparatus and a device under test is provided. The testing connector includes an electric power conduction portion and a signal conduction portion. The electric power conduction portion has a first length which is a distance from a lower end of the electric power conduction portion to an upper end of the electric power conduction portion in a non-pressed state, and the signal conduction portion has a second length which is a distance from a lower end of the signal conduction portion to an upper end of the signal conduction portion in the non-pressed state. The second length is shorter than the first length. When a pressing force is applied to the testing connector, the electric power conduction portion is compressed before the signal conduction portion is compressed.

### TECHNICAL FIELD

The present disclosure relates to a testing connector, which is disposed between a test apparatus and a device under test and is used for testing of the device under test.

### BACKGROUND

During testing of a device under test such as a semiconductor device, a testing connector electrically connecting a test apparatus and the device under test is used. The testing connector is disposed between the test apparatus and the device under test. A pogo pin connector or a conductive rubber connector are known as an example of the testing connector. The conductive rubber connector has a conduction portion made of conductive particles and elastic substance.

A semiconductor device for use with a mobile communication device undergoes a high frequency test. Since the conductive rubber connector having a thickness thinner than the pogo pin connector shows a good RF property, the conductive rubber connector is used for the high frequency test. By way of example, Japanese Patent Application Publication No. 2004-335450 proposes a testing connector that can be used for the high frequency test.

The testing connector of a prior art technique for use in the high frequency test has a conduction portion for signal transmission, a conduction portion for electric power supply, a conduction portion for grounding, and a metal housing in which those conduction portions are disposed. The conduction portions are disposed in the metal housing in a state of being insulated from the metal housing. During testing of the device under test, a pressing force is applied to the device under test, and the device under test presses the conduction portions of the testing connector by the pressing force. The testing connector of the prior art technique cannot prevent deformation of the conduction portion for signal transmission, and cannot ensure highly reliable function of the conduction portion for electric power supply or the conduction portion for grounding.

### SUMMARY

The present disclosure provides a testing connector that solves the aforementioned problems of the prior art technique. At least one embodiment of the present disclosure provides a testing connector that is advantageous for impedance matching since the conduction portion for signal transmission does not cause shape deformation during testing of the device under test. At least one embodiment of the present disclosure provides a testing connector in which the shape deformation of the conduction portion for signal transmission is prevented and the conduction portion of electric power supply and the conduction portion for grounding show an appropriate stroke. At least one embodiment of the present disclosure provides a testing connector that realizes a weak contact strength between the terminal of the device under test and the conduction portion for signal transmission to prevent damage.

A testing connector according to embodiments of the present disclosure is disposed between a test apparatus and a device under test, and can be used for testing of the device under test. The testing connector according to one embodiment includes an electric power conduction portion and a signal conduction portion. The electric power conduction portion has a first length which is a distance from a lower end of the electric power conduction portion to an upper end of the electric power conduction portion in a non-pressed state. The signal conduction portion has a second length which is a distance from a lower end of the signal conduction portion to an upper end of the signal conduction portion in the non-pressed state. The second length is shorter than the first length. When a pressing force is applied to the testing connector, the electric power conduction portion is compressed before the signal conduction portion is compressed.

In one embodiment, in the non-pressed state, the second length is shorter than the first length by a length difference equal to 5% to 15% of the first length.

In one embodiment, the length difference may be defined by a height difference between the upper end of the electric power conduction portion and the upper end of the signal conduction portion.

In one embodiment, the length difference may be defined by a height difference between the lower end of the electric power conduction portion and the lower end of the signal conduction portion.

In one embodiment, the signal conduction portion may include an upper signal conduction portion and a lower signal conduction portion, which are separated from each other and are spaced apart. The length difference may be defined by a spaced distance between the upper signal conduction portion and the lower signal conduction portion.

In one embodiment, the electric power conduction portion may include a protruding conduction portion, which protrudes more upward than the upper end of the signal conduction portion and has a length corresponding to the length difference. An upper end of the protruding conduction portion forms the upper end of the electric power conduction portion.

In one embodiment, in the non-pressed state, the upper end of the signal conduction portion may be positioned below the upper end of the electric power conduction portion.

In one embodiment, in the non-pressed state, the lower end of the signal conduction portion may be positioned above the lower end of the electric power conduction portion.

The testing connector according to one embodiment includes a grounding conduction portion. The grounding conduction portion has a third length which is a length from a lower end of the grounding conduction portion to an upper end of the grounding conduction portion, and the second length of the signal conduction portion is shorter than the third length of the grounding conduction portion.

The testing connector according to one embodiment includes: a housing having a first through hole, in which the signal conduction portion is disposed and which is perforated through in an up-and-down direction, and a second through hole, in which the electric power conduction portion is disposed and which is perforated through in the up-and-down direction; a first insulation portion disposed in the first through hole, insulating the signal conduction portion from the housing, and positioning the signal conduction portion coaxially with a central axis of the first through hole; and a second insulation portion disposed in the second through hole and insulating the electric power conduction portion from the housing.

In one embodiment, the first insulation portion includes a first lower insulation portion and a first upper insulation portion, which are disposed at a lower side and an upper side of the first through hole, respectively. An inner peripheral surface of the first through hole, an upper surface of the first lower insulation portion, and a lower surface of the first upper insulation portion form an insulation space surrounding an outer peripheral surface of the signal conduction portion.

In one embodiment, the housing includes: a first housing having first and second lower through holes forming the first and second through holes, respectively; and a second housing having first and second upper through holes forming the first and second through holes, respectively, and disposed on the first housing. The first insulation portion includes a first lower insulation portion and a first upper insulation portion, which are disposed in the first lower through hole and the first upper through hole, respectively. The second insulation portion includes a second lower insulation portion and a second upper insulation portion, which are disposed in the second lower through hole and the second upper through hole, respectively.

In one embodiment, by the signal conduction portion and the electric power conduction portion, the second housing may be spaced apart from the first housing and may be supported with respect to the first housing.

In one embodiment, the signal conduction portion includes: a lower signal conduction portion coupled to the first lower insulation portion; and an upper signal conduction portion coupled to the first upper insulation portion, spaced apart upward from the lower signal conduction portion by a switch gap in the non-pressed state, and conductively coming in contact with the lower signal conduction portion in a pressed state. In the non-pressed state, an up-and-down directional length of the switch gap may be equal to a length difference of the first length and the second length.

In one embodiment, the lower signal conduction portion and the upper signal conduction portion may have different diameters from each other.

In one embodiment, the electric power conduction portion may be coupled to the second upper insulation portion and may be insertable into the second lower insulation portion.

In one embodiment, the housing may further include an elastic insulation housing, which is disposed between the first housing and the second housing and has insertion holes becoming a portion of the first upper through hole and the second upper through hole.

In one embodiment, the signal conduction portion includes: a lower signal conduction portion coupled to the first lower insulation portion; and an upper signal conduction portion coupled to the first upper insulation portion, spaced apart upward from the lower signal conduction portion by a first switch gap in the non-pressed state, and conductively coming in contact with the lower signal conduction portion in a pressed state. The electric power conduction portion includes: a lower electric power conduction portion coupled to the second lower insulation portion; and an upper electric power conduction portion coupled to the second upper insulation portion, spaced apart upward from the lower electric power conduction portion by a second switch gap in the non-pressed state, and conductively coming in contact with the lower electric power conduction portion in the pressed state. In the non-pressed state, a length of the first switch gap in the up-and-down direction may be a sum of a length of the second switch gap in the up-and-down direction and a length difference of the first length and the second length.

The testing connector according to one embodiment further includes: a grounding conduction portion disposed in the up-and-down direction in a third through hole of the housing perforated through in the up-and-down direction; and a third insulation portion disposed in the third through hole. In the non-pressed state, the grounding conduction portion has a third length, which is a distance between a lower end and an upper end of the grounding conduction portion and is longer than the second length.

In one embodiment, in the non-pressed state, the upper end of the signal conduction portion may be positioned below the upper end of the grounding conduction portion.

In one embodiment, in the non-pressed state, the lower end of the signal conduction portion may be positioned above the lower end of the grounding conduction portion.

In one embodiment, the electric power conduction portion and the grounding conduction portion may have a diameter greater than a diameter of the signal conduction portion.

According to at least one embodiment of the present disclosure, the signal conduction portion in the non-pressed state has a length shorter than a length of the electric power conduction portion by the length difference equal to 5% to 15% of the length of the electric power conduction portion. Therefore, when the conduction portions change from the non-pressed state to the pressed state during testing of the device under test, the electric power conduction portion can be first pressed by the pressing force prior to the signal conduction portion, and the signal conduction portion can come in contact with the terminal of the device under test in the state of hardly being pressed. Accordingly, in the pressed state during testing of the device under test, the shape of the signal conduction portion in the non-pressed state can be maintained, the spaced distance between the signal conduction portion and the through hole of the housing can be maintained constantly from the lower end of the signal conduction portion to the upper end of the signal conduction portion, and matched impedance and improved test reliability of the connector can be achieved.

According to at least one embodiment of the present disclosure, due to the signal conduction portion having a length shorter than the electric power conduction portion by the length difference, the pressing force of a reference value capable of lowering resistance can be applied to the electric power conduction portion and the grounding conduction portion, and the electric power conduction portion and the grounding conduction portion can exhibit a stroke allowing good elastic restoration. Further, the signal conduction portion can exhibit good signal transmission property without being deformed from the shape in the non-pressed state.

According to at least one embodiment of the present disclosure, during testing of the device under test, the signal conduction portion can maintain the shape of the non-pressed state, and the electric power conduction portion and the grounding conduction portion can be pressed with a stroke of a reference value so as to exhibit low resistance. Accordingly, the signal conduction portion can be formed so as to have a small diameter in order to improve signal transmission property, and the electric power conduction portion and the grounding conduction portion can be formed so as to have an appropriate diameter greater than the signal conduction portion in order to operate desirably.

### BRIEF DESCRIPTION OF DRAWINGS

FIG. 1 schematically shows an example where a connector according to embodiments of the present disclosure is used.

FIG. 2 is a sectional view showing a portion of a connector according to a first embodiment of the present disclosure.

FIG. 3 is a sectional perspective view showing the portion of the connector shown in FIG. 2.

FIG. 4 is a sectional view schematically showing a non-pressed state and a pressed state of a conduction portion in the portion of the connector shown in FIG. 2.

FIG. 5 is a sectional view showing a portion of a connector according to a second embodiment of the present disclosure.

FIG. 6 is an exploded sectional view of the portion of the connector shown in FIG. 5.

FIG. 7 is a sectional view showing a portion of a connector according to third embodiment of the present disclosure.

FIG. 8 is a sectional view showing a portion of a connector according to fourth embodiment of the present disclosure.

FIG. 9 is a sectional view showing a portion of a connector according to a fifth embodiment of the present disclosure.

FIG. 10 is an exploded sectional view of the portion of the connector shown in FIG. 9.

FIG. 11 is a sectional view schematically showing a non-pressed state and a pressed state of a conduction portion in the portion of the connector shown in FIG. 9.

FIG. 12 is a sectional view showing a portion of a connector according to a sixth embodiment of the present disclosure.

FIG. 13 is a sectional view showing a portion of a connector according to a seventh embodiment of the present disclosure.

FIG. 14 is an exploded sectional view of the portion of the connector shown in FIG. 13.

FIG. 15 is a graph showing a result of a high frequency test simulation on a connector according to a comparative example, wherein a second length of a signal conduction portion is shorter than a first length of an electric power conduction portion by a length difference of less than 5% of the first length.

FIG. 16 is a graph showing a result of a high frequency test simulation on a connector according to one embodiment, wherein the second length of the signal conduction portion is shorter than the first length of the electric power conduction portion by a length difference of 5% of the first length.

FIG. 17 is a graph showing a result of a high frequency test simulation on a connector according to one embodiment, wherein the second length of the signal conduction portion is shorter than the first length of the electric power conduction portion by a length difference of 10% of the first length.

FIG. 18 is a graph showing a result of a high frequency test simulation on a connector according to one embodiment, wherein the second length of the signal conduction portion is shorter than the first length of the electric power conduction portion by a length difference of 15% of the first length.

FIG. 19 is a boxplot chart showing a result of a resistance test simulation on a connector according to one embodiment, wherein the second length of the signal conduction portion is shorter than the first length of the electric power conduction portion by a length difference of 5% of the first length.

FIG. 20 is a boxplot chart showing a result of a resistance test simulation on a connector according to one embodiment, wherein the second length of the signal conduction portion is shorter than the first length of the electric power conduction portion by a length difference of 10% of the first length.

FIG. 21 is a boxplot chart showing a result of a resistance test simulation on a connector according to one embodiment, wherein the second length of the signal conduction portion is shorter than the first length of the electric power conduction portion by a length difference of 15% of the first length.

FIG. 22 is a boxplot chart showing a result of a resistance test simulation on a connector according to a comparative example, wherein the second length of the signal conduction portion is shorter than the first length of the electric power conduction portion by a length difference of 20% of the first length.

### DETAILED DESCRIPTION

Embodiments of the present disclosure are illustrated for the purpose of explaining the technical idea of the present disclosure. The scope of the rights according to the present disclosure is not limited to the embodiments presented below or the detailed descriptions of such embodiments.

All technical terms and scientific terms used in the present disclosure include meanings that are commonly understood by those of ordinary skill in the technical field to which the present disclosure pertains unless otherwise defined. All terms used in the present disclosure are selected for the purpose of describing the present disclosure more clearly, and are not selected to limit the scope of the rights according to the present disclosure.

Expressions such as “comprising,” “including,” “having,” and the like used in the present disclosure are to be understood as open-ended terms having the possibility of encompassing other embodiments, unless otherwise stated in the phrase or sentence containing such expressions.

Singular expressions described in the present disclosure may encompass meanings of a plural form unless otherwise stated, which will also apply to singular expressions recited in the claims.

Expressions such as “first,” “second,” etc. used in the present disclosure are used to distinguish a plurality of elements from one another, and are not intended to limit an order or importance of the elements.

In the present disclosure, the description that one element is “connected” or “coupled” to another element should be understood to indicate that the aforesaid one element may be directly connected or coupled to the aforesaid another element, and should be further understood that the aforesaid one element may be connected or coupled to the aforesaid another element via a new element.

A directional term “upward” used in the present disclosure is based on a direction in which a connector is positioned with respect to a test apparatus, while the directional term “downward” means a direction opposite to the upward direction. A directional term “up-and-down direction” used in the present disclosure may include an upward direction and a downward direction, but it is to be understood not to mean a particular one direction between the upward direction and the downward direction. A horizontal direction used in the present disclosure is a direction orthogonal to the up-and-down direction. When the up-and-down direction is assumed as a Y-axis, the horizontal direction may be a direction located in an X-axis plane.

Hereinafter, the embodiments are described with reference to examples shown in the accompanying drawings. Like reference symbols in the accompanying drawings denote like or corresponding elements. Further, in the following descriptions of the embodiments, redundant descriptions for the same or corresponding elements may be omitted. However, even if the descriptions of the elements are omitted, such elements are not intended to be excluded in any embodiment.

The embodiments described below and the examples shown in the accompanying drawings are directed to a testing connector (hereinafter, simply referred to as a connector) used for testing of a device under test. The connector of the embodiments is disposed between a test apparatus and the device under test when testing the device under test, and can be used for testing of the device under test. By way of example, in a post-process of manufacturing processes of a semiconductor device, the connector of the embodiments can be used for final testing of the semiconductor device. However, the test example to which the connector of the embodiments are applied is not limited to the aforementioned testing.

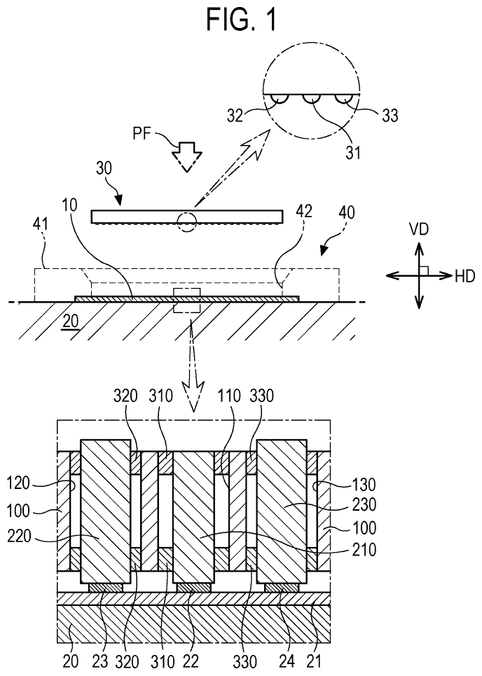

Reference is made to FIG. 1 showing an example where the connector according to the embodiments of the present disclosure is used. FIG. 1 schematically shows shapes of the connector, a part to which the connector is attached, the test apparatus, and the device under test. The shapes shown in FIG. 1 are merely examples selected for purposes of understanding the embodiments.

The connector 10 is a sheet-shaped structure, and is disposed between the test apparatus 20 and the device under test 30. The connector 10 may be a component of a test socket. By way of example, the connector 10 may be attached to a socket housing 40, and may be positioned on the test apparatus 20 by the socket housing 40. The socket housing 40 may have a socket guide 41, and an accommodation hole 42 may be formed in the socket guide 41 in an up-and-down direction VD. The socket housing 40 may be removably mounted on the test apparatus 20 at the socket guide 41, and the connector 10 may be removably coupled to the socket guide 41. The device under test 30, which is transferred to the test apparatus 20 manually or by a transfer device, is accommodated in the accommodation hole 42 of the socket housing, and the socket housing 40 aligns the device under test 30 with respect to the connector 10. During testing of the device under test 30, the connector 10 comes in contact with the test apparatus 20 and the device under test 30 in the up-and-down direction VD, and electrically connects the test apparatus 20 and the device under test 30 to each other. By way of example, the connector 10 may be disposed between the device under test 30 and the test apparatus 20 for a high frequency test of the device under test 30.

The device under test 30 may be a semiconductor device that is obtained by packaging a semiconductor IC chip and numerous terminals into a hexahedral form by using a resin material. By way of example, the device under test 30 may be a semiconductor device for use in a mobile communication device, but is not limited thereto. The device under test 30 may have, at its underside, a multiple number of terminals. By way of example, the device under test 30 may have a signal terminal 31, an electric power terminal 32, and a grounding terminal 33. The arrangement of the terminals of the device under test shown in FIG. 1 is only illustrative. In an area of the underside of the device under test, only the signal terminal 31 may be disposed. In another area of the underside of the device under test 30, the signal terminal 31 and the electric power terminal 32 may be disposed. In yet another area of the underside of the device under test 30, the signal terminal 31, the electric power terminal 32, and the grounding terminal 33 may be disposed.

The test apparatus 20 may test electrical properties and operational properties of the device under test 30. The test apparatus 20 may have a board on which the testing is performed, and a testing circuit 21 for the testing of the device under test may be provided in the board. The testing circuit 21 has a plurality of pads 22, 23, and 24 electrically connected to the terminals of the device under test through the connector. The pad 22 can transmit electrical test signals and can receive response signals. The pad 23 can apply electric power to the device under test 30, and the pad 24 can function as a ground.

The connector 10 according to one embodiment includes a housing 100, conduction portions 210, 220, and 230, and insulation portions 310, 320, and 330. The housing 100 is a component for disposing the conduction portions in the up-and-down direction VD, and may constitute a main body of the connector. The housing 100 is attached to the socket guide 41 of the socket housing 40, and may be positioned in a horizontal direction HD.

The conduction portions 210, 220, and 230 are configured to be conductive in the up-and-down direction VD. The conduction portions 210, 220, and 230 are disposed in through holes 110, 120, and 130 of the housing 100, and perform the function of signal transmission, electric power supply, and grounding. The insulation portions 310, 320, and 330 are disposed between the housing 100 and the conduction portions 210, 220, and 230, and insulate the conduction portions from the housing or fix the conduction portions to the housing. The insulation portions 310, 320, and 330 may be disposed in the through holes so as to almost fill the through holes 110, 120, and 130 of the housing, or may be disposed in the through holes so as to form an empty space in the through holes 110, 120, and 130. According to one embodiment of the connector, the aforesaid conduction portions include a signal conduction portion 210, an electric power conduction portion 220, and a grounding conduction portion 230. The aforesaid insulation portions of the connector include a first insulation portion 310 insulating the signal conduction portion 210 from the housing, a second insulation portion 320 insulating the electric power conduction portion 220 from the housing, and a third insulation portion 330 supporting the grounding conduction portion 230.

When the connector 10 is disposed on the test apparatus 20 for testing of the device under test, the signal conduction portion 210, the electric power conduction portion 220, and the grounding conduction portion 230 are positioned in the up-and-down direction VD. The signal conduction portion 210 comes in contact with the signal terminal 31 and the pad 22 in the up-and-down direction VD, and performs the signal transmission between the test apparatus 20 and the device under test 30. The electric power conduction portion 220 comes in contact with the electric power terminal 32 and the pad 23 in the up-and-down direction VD, and supplies electric power to the device under test. The grounding conduction portion 230 comes in contact with the grounding terminal 33 and the pad 24 in the up-and-down direction VD.

The connector 10 may include a plurality of signal conduction portions 210, at least one electric power conduction portion 220, and at least one grounding conduction portion 230. By way of example, the signal conduction portions 210 may be arranged in the form of one matrix, or in the form of one or more pairs of matrices. The arrangement of the signal conduction portion 210, the electric power conduction portion 220, and the grounding conduction portion 230 may vary depending on an arrangement of the terminals of the device under test 30. The arrangement of the conduction portions shown in FIG. 1 is only an example, and the arrangement of the conduction portions may vary in accordance with areas of the housing 100. In accordance with areas of the housing 100, only a plurality of signal conduction portions 210 may be disposed, the electric power conduction portion 220 may be disposed beside the plurality of signal conduction portions 210, the signal conduction portion 210 and the electric power conduction portion 220 may be disposed side by side, or the signal conduction portion 210 and the grounding conduction portion 230 may be disposed side by side. Thus, in accordance with areas of the housing, the connector may include only the signal conduction portion 210 and the electric power conduction portion 220, or may include the signal conduction portion 210, the electric power conduction portion 220, and the grounding conduction portion 230.

During testing of the device under test, a pressing force PF is applied to the device under test 30 by a machine device or manually. The terminals 31, 32, and 33 of the device under test receiving the pressing force PF apply the pressing force to the connector 10. As the terminals 31, 32, and 33 of the device under test press the conduction portions 210, 220, and 230 downward, the conduction portions 210, 220, and 230 may be elastically deformed so as to be compressed downward and to be expanded in the horizontal direction HD. When the pressing force PF is removed from the device under test, the conduction portions 210, 220 and 230 can be restored to their original shapes.

During a high frequency test of the device under test, a high frequency signal is applied to the signal conduction portion 210. If a shape of the signal conduction portion 210 is deformed by the pressing force PF, signal loss may occur at the signal conduction portion 210 due to the characteristics of the high frequency. Thus, it is necessary that the shape of the signal conduction portion 210 is not deformed due to excessive pressing. In contrast, during the high frequency test, the electric power conduction portion 220 is not used for transmission of the high frequency signal. Thus, in order for the electric power conduction portion 220 to show low resistance, it is preferable that the electric power conduction portion 220 receives a stronger pressing force. Even if a shape of the electric power conduction portion is deformed by the strong pressing force, the electric power conduction portion can have a low resistance, and the grounding conduction portion 230 can also have a low resistance despite shape deformation caused by the strong pressing force. Accordingly, in the connector for use in the high frequency test, the pressing forces suitable for the signal conduction portion 210, the electric power conduction portion 220, and the grounding conduction portion 230 are not the same.

It may be preferable to use a stronger pressing force on the electric power conduction portion 220 and the grounding conduction portion 230 in comparison with the signal conduction portion 210. In contrast, it may be preferable to use a weaker pressing force on the signal conduction portion 210 in comparison with the electric power conduction portion 220. If the strong pressing force PF is applied to the testing connector through the device under test such that the electric power conduction portion 220 and the grounding conduction portion 230 are pressed beyond a certain reference value, then the signal conduction portion 210 may be deformed excessively. Due to the strong pressing force, the signal conduction portion 210 may be deformed in the form of buckling or bulging in its middle portion. The excessively deformed signal conduction portion 210 shows degraded signal transmission property, and may cause signal loss. It is important that the connector for the high frequency test shows an impedance matching with an impedance of the device under test and an impedance of the test apparatus, but the excessively deformed signal conduction portion 210 fails to achieve impedance matching. Further, due to the strong pressing force, the terminals of the device under test and the signal conduction portion 210 may be damaged. In contrast, if a low pressing force is applied to the connector to the extent of not deforming the shape of the signal conduction portion 210, the electric power conduction portion 220 and the grounding conduction portion 230 cannot exhibit a low resistance, and thus cannot perform a conduction function.

However, during the testing of the device under test where the pressing force is applied, the connector 10 according to one embodiment can prevent a shape change of the signal conduction portion 210 and can allow the electric power conduction portion 220 and the grounding conduction portion 230 to have a low resistance. Specifically, the signal conduction portion 210 and the electric power conduction portion 220 have different lengths in the up-and-down direction VD, and therefore the signal conduction portion 210 can come in contact with the signal terminal 31 and the pad 22 in an almost unpressed state.

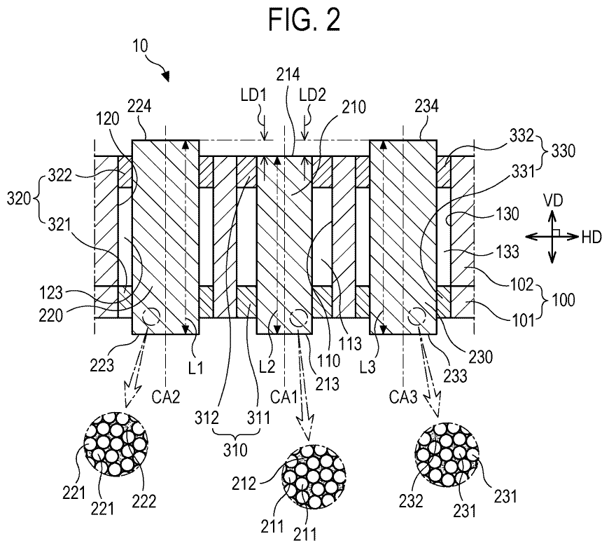

Reference is made to FIGS. 2 to 14 for descriptions of the embodiments of the connector. FIGS. 2 to 14 schematically show shapes and numbers of the elements of the connector. The shapes and numbers of the elements of the connector shown in FIGS. 2 to 14 are examples selected for purposes of understanding the embodiments of the connector.

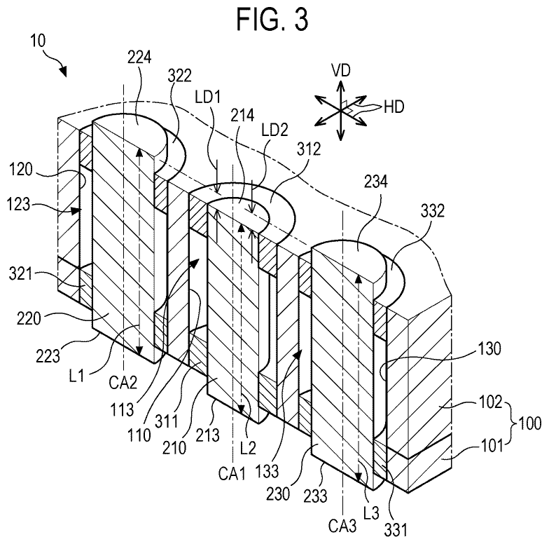

FIG. 2 is a sectional view showing a portion of a connector according to a first embodiment of the present disclosure, and FIG. 3 is a sectional perspective view showing the portion of the connector shown in FIG. 2. Reference is made to FIGS. 2 and 3 in the below descriptions.

The connector 10 shown in FIG. 2 includes the housing 100, the signal conduction portion 210, the electric power conduction portion 220, the grounding conduction portion 230, the first insulation portion 310, the second insulation portion 320, and the third insulation portion 330. The portion of the connector shown in FIG. 2 includes the electric power conduction portion 220 and the grounding conduction portion 230 that are spaced apart from the signal conduction portion 210 in the horizontal direction HD. In accordance with some areas of the housing, the connector 10 may include the signal conduction portion 210 and the electric power conduction portion 220.

The aforesaid conduction portions are disposed in the housing 100 in the up-and-down direction VD. By way of example, the housing 100 may be made of a metallic material, and may be formed in a shape of a thin flat plate. The metallic material constituting the housing 100 may be aluminum or stainless steel, but is not limited thereto. The housing 100 made of a metallic material can prevent cross talk between adjacent conduction portions and shield electromagnetic waves. The housing 100 may be coated with an insulating material to prevent a short circuit between the conduction portions.

The housing 100 has a plurality of through holes, and the signal conduction portion 210, the electric power conduction portion 220, and the grounding conduction portion 230 are disposed in the respective through holes of the housing. According to one embodiment of the connector, the housing 100 has a first through hole 110, a second through hole 120, and a third through hole 130. Each through hole is perforated through the housing 100 in the up-and-down direction VD. Each through hole may have a circular cross-sectional shape. Each through hole is formed so as to be perforated through the housing 100 in the up-and-down direction VD from a lower surface of the housing 100 to an upper surface of the housing 100. The housing 100 may be one part, but a plurality of housings may constitute the housing 100 by being stacked in the up-and-down direction. According to one embodiment of the connector, the housing 100 may include a first housing 101 and a second housing 102. The second housing 102 is disposed on the first housing 101, and the first housing 101 and the second housing 102 may be coupled by bonding. Each of the through holes of the housing 100 may be partially formed in the first housing 101 and the second housing 102.

The signal conduction portion 210 is disposed in the first through hole 110 in the up-and-down direction VD coaxially with a central axis CA1 of the first through hole 110. The signal conduction portion 210 is disposed in the first through hole 110 so as to be spaced apart from an inner peripheral surface of the first through hole (e.g., such that an outer peripheral surface of the signal conduction portion and the inner peripheral surface of the first through hole are spaced apart from each other in a radially outward direction of the central axis CA1). The signal conduction portion 210 is configured to be conductive in the up-and-down direction, and performs signal transmission between the pad of the test apparatus and the signal terminal of the device under test. The signal conduction portion comes in contact, at its lower end 213, with the pad of the test apparatus, and comes in contact, at its upper end 214, with the signal terminal of the device under test. The signal conduction portion 210 may have a cylindrical shape extending in the up-and-down direction VD.

The first insulation portion 310 disposed in the first through hole 110 supports the signal conduction portion 210 in the up-and-down direction VD. The first insulation portion is configured to position the signal conduction portion coaxially with the central axis CA1 of the first through hole. The first insulation portion 310 is configured to insulate the signal conduction portion 210 with respect to the housing 100.

The first insulation portion 310 is disposed between the outer peripheral surface of the signal conduction portion 210 and the inner peripheral surface of the first through hole 110, and is formed so as to fill an annular space formed between the inner peripheral surface of the first through hole and the outer peripheral surface of the signal conduction portion. The first insulation portion 310 is formed so as to surround the signal conduction portion 210 in a circumferential direction of the central axis CA1. The first insulation portion 310 may have a ring shape corresponding to the aforementioned annular space. A width of the first insulation portion 310 in a radially outward direction of the central axis CA1 may be constant along the circumferential direction of the central axis CA1. Accordingly, the signal conduction portion 210 supported by the first insulation portion 310 can be disposed coaxially with the central axis CA1 in the first through hole 110.

According to one embodiment of the connector, the first insulation portion 310 includes a first lower insulation portion 311 disposed at a lower side of the first through hole 110, and a first upper insulation portion 312 disposed at an upper side of the first through hole. The first lower insulation portion 311 and the first upper insulation portion 312 are formed in a ring shape, and are coupled to an upper portion and a lower portion of the signal conduction portion, respectively. Therefore, an insulation space 113 filled with air is formed inside the first through hole 110. The insulation space 113 is defined by the inner peripheral surface of the first through hole 110, the outer peripheral surface of the signal conduction portion 210, an upper surface of the first lower insulation portion 311, and a lower surface of the first upper insulation portion 312. The insulation space 113 surrounds the outer peripheral surface of the signal conduction portion 210 around the central axis CA1.

The electric power conduction portion 220 is configured to be conductive in the up-and-down direction VD, and functions for electric power supply from the test apparatus to the device under test. During testing of the device under test, the electric power conduction portion 220 comes in contact, at its lower end 223, with the pad of the test apparatus, and comes in contact, at its upper end 224, with the electric power terminal of the device under test. The electric power conduction portion 220 may have a cylindrical shape extending in the up-and-down direction VD.

The electric power conduction portion 220 is disposed in the second through hole 120 in the up-and-down direction VD. The electric power conduction portion 220 is disposed in the second through hole 120 so as to be spaced apart from an inner peripheral surface of the second through hole (e.g., such that an outer peripheral surface of the electric power conduction portion and the inner peripheral surface of the second through hole are spaced apart from each other in a radially outward direction of a central axis CA2 of the second through hole). The electric power conduction portion 220 is disposed so as to be spaced apart from the inner peripheral surface of the second through hole by the second insulation portion 320. Further, the electric power conduction portion 220 may be positioned coaxially with the central axis CA2 of the second through hole 120 by the second insulation portion 320. The second insulation portion 320 supports the electric power conduction portion 220 in the up-and-down direction VD, and is configured to insulate the electric power conduction portion 220 from the housing 100.

The second insulation portion 320 has a ring shape, and is disposed between the outer peripheral surface of the electric power conduction portion 220 and the inner peripheral surface of the second through hole 120. The second insulation portion 320 fills an annular space formed between the inner peripheral surface of the second through hole and the outer peripheral surface of the electric power conduction portion, and surrounds the electric power conduction portion along a circumferential direction of the central axis CA2 of the second through hole. A width of the second insulation portion 320 in a radially outward direction of the central axis CA2 may be constant along the circumferential direction of the central axis CA2. Accordingly, the second insulation portion 320 can position the electric power conduction portion 220 coaxially with the central axis CA2 in the second through hole.

According to one embodiment of the connector, the second insulation portion 320 includes a second lower insulation portion 321 disposed at a lower side of the second through hole, and a second upper insulation portion 322 disposed at an upper side of the second through hole. The second lower insulation portion 321 and the second upper insulation portion 322 are formed in a ring shape, and are coupled to an upper portion and a lower portion of the electric power conduction portion, respectively. Therefore, an insulation space 123 filled with air is formed inside the second through hole 120. The insulation space 123 is defined by the inner peripheral surface of the second through hole 120, the outer peripheral surface of the electric power conduction portion 220, an upper surface of the second lower insulation portion 321, and a lower surface of the second upper insulation portion 322. The insulation space 123 surrounds the outer peripheral surface of the electric power conduction portion 220 around the central axis CA2.

The grounding conduction portion 230 comes in contact with the grounding terminal of the device under test and the pad of the test apparatus in the up-and-down direction VD, and is configured to be conductive in the up-and-down direction. The grounding conduction portion 230 is disposed in the third through hole 130 in the up-and-down direction VD. The grounding conduction portion 230 may have a cylindrical shape extending in the up-and-down direction VD.

The grounding conduction portion 230 is supported by the third insulation portion 330 in the up-and-down direction VD in the third through hole 130. The grounding conduction portion 230 may be positioned coaxially with a central axis CA3 of the third through hole by the third insulation portion. The third insulation portion 330 has a ring shape. The third insulation portion 330 is disposed between an outer peripheral surface of the grounding conduction portion and an inner peripheral surface of the third through hole, and fills an annular space formed between the inner peripheral surface of the third through hole and the outer peripheral surface of the grounding conduction portion. A width of the third insulation portion 330 in a radially outward direction of the central axis CA3 of the third through hole may be constant along a circumferential direction of the central axis CA3.

According to one embodiment of the connector, the third insulation portion 330 includes a third lower insulation portion 331 disposed at a lower side of the third through hole, and a third upper insulation portion 332 disposed at an upper side of the third through hole. The third lower insulation portion 331 and the third upper insulation portion 332 are formed in a ring shape, and are coupled to an upper portion and a lower portion of the grounding conduction portion, respectively. Therefore, an insulation space 133 filled with air is formed inside the third through hole 130. The insulation space 133 is defined by the inner peripheral surface of the third through hole 130, the outer peripheral surface of the grounding conduction portion 230, an upper surface of the third lower insulation portion 331, and a lower surface of the third upper insulation portion 332. The insulation space 123 surrounds the outer peripheral surface of the grounding conduction portion 230 around the central axis CA3.

The signal conduction portion 210, the electric power conduction portion 220, and the grounding conduction portion 230 are not only conductive in the up-and-down direction, but also capable of elastically deforming by the pressing force. According to one embodiment of the connector, each of the signal conduction portion 210, the electric power conduction portion 220, and the grounding conduction portion 230 includes a multiple number of conductive particles and an elastic substance. The signal conduction portion 210 includes a conductive particle 211 and an elastic substance 212, the electric power conduction portion 220 includes a conductive particle 221 and an elastic substance 222, and the grounding conduction portion 230 includes a conductive particle 231 and an elastic substance 232. The conductive particles 211, 221, and 231 of the respective conduction portions may be the same, or may be different from one another. The elastic substances 212, 222, and 232 of the respective conduction portions may be the same, or may be different from one another.

The multiple number of conductive particles 211, 221, and 231 of the respective conduction portions are grouped together in a circular column shape so as to be conductive in the up-and-down direction VD, and the neighboring conductive particles may conductively come in contact with each other so as to be conductive in any direction. The multiple number of conductive particles 211, 221, and 231 grouped together in the up-and-down direction function as a conductor between the pad of the test apparatus and the terminal of the device under test. The conductive particles 211, 221, and 231 may be made of a highly conductive metallic material. Alternatively, the conductive particles 211, 221, and 231 may have a form that the aforesaid highly conductive metallic material is coated on a core made of an elastic resin material or a metallic material.

The elastic substances 212, 222, and 232 of the respective conduction portions are in a state of being hardened, and has elasticity. The elastic substances 212, 222, and 232 maintain the conductive particles in the up-and-down direction VD such that the conductive particles 211, 221, and 231 are grouped together in the circular column shape. The elastic substance may be filled between the conductive particles. The conductive particles and the elastic substance are integrally formed, thereby constituting each conduction portion. By way of example, the elastic substance may be hardened silicone rubber, but is not limited thereto.

The first insulation portion 310, the second insulation portion 320, and the third insulation portion 330 may be made of a material having an insulation property and elasticity. By way of example, each insulation portion may be made of silicone rubber. The material constituting each insulation portion is not limited to silicone rubber, and may be a fluorine-based material having a low dielectric permittivity, such as Teflon.

Each conduction portion 210, 220, and 230 including the elastic substance is elastically deformable in the up-and-down direction VD and the horizontal direction HD. During testing of the device under test, the pressing force (the pressing force indicated by symbol PF in FIG. 1) is applied to the device under test. The terminal of the device under test presses the conduction portion corresponding thereto by the pressing force, and the conduction portion can be elastically deformed in the up-and-down direction VD and the horizontal direction HD. Hereinafter, a state where the signal conduction portion 210, the electric power conduction portion 220, and the grounding conduction portion 230 are elastically deformed by the pressing force is referred to as a pressed state of the conduction portion. In the pressed state, each conduction portion 110 can be elastically deformed so as to be compressed downward while being slightly expanded in the horizontal direction HD. As the testing of the device under test ends and the pressing force is removed from the device under test, each conduction portion can be elastically restored from the pressed state to its original shape. Hereinafter, a state of the signal conduction portion 210, the electric power conduction portion 220, and the grounding conduction portion 230 where the pressing force is not applied to the connector is referred to as a non-pressed state of the conduction portion. As such, each conduction portion can be elastically deformed into the non-pressed state and the pressed state.

In the portion of the connector shown in FIG. 2, the lower end 213 of the signal conduction portion 210, the lower end 223 of the electric power conduction portion 220, and the lower end 233 of the grounding conduction portion 230 protrude from a lower surface of the housing 100. Each conduction portion may be disposed in the housing 100 such that the lower end 213 of the signal conduction portion, the lower end 223 of the electric power conduction portion, and the lower end 233 of the grounding conduction portion are positioned at the same level. Each conduction portion shown in FIG. 2 is in the non-pressed state.

According to one embodiment of the connector, in the non-pressed state of the signal conduction portion 210, the electric power conduction portion 220, and the grounding conduction portion 230, the electric power conduction portion 220 has a first length L1, which is an up-and-down directional distance ranging from the lower end 223 to the upper end 224. The first length L1 may be a numerical value obtained by measuring the distance between the lower end 223 and the upper end 224 of the electric power conduction portion in the non-pressed state in the up-and-down direction VD, and may correspond to an up-and-down directional thickness of the electric power conduction portion. In the non-pressed state, the signal conduction portion 210 has a second length L2, which is an up-and-down directional distance ranging from the lower end 213 to the upper end 214. The second length L2 may be a numerical value obtained by measuring the distance between the lower end 213 and the upper end 214 of the signal conduction portion in the non-pressed state in the up-and-down direction VD, and may correspond to an up-and-down directional thickness of the signal conduction portion. In the non-pressed state, the grounding conduction portion 230 has a third length L3, which is an up-and-down directional distance ranging from the lower end 233 to the upper end 234. The third length L3 may be a numerical value obtained by measuring the distance between the lower end 233 and the upper end 234 of the grounding conduction portion in the non-pressed state in the up-and-down direction VD, and may correspond to an up-and-down directional thickness of the grounding conduction portion.

The second length L2 has a numerical value less than the first length L1. The second length L2 is shorter than the first length L1 by a predetermined length difference LD1. The length difference LD1 is a length difference of the first length L1 and the second length L2. Thus, the signal conduction portion 210 has a length shorter than an up-and-down directional length of the electric power conduction portion 220. The length difference LD1 may be defined by an up-and-down directional height difference between the upper end 224 of the electric power conduction portion and the upper end 214 of the signal conduction portion. The second length L2 is shorter than the third length L3, and the third length L3 has a numerical value greater than the second length L2. The third length L3 is longer than the second length L2 by a predetermined length difference LD2. The length difference LD2 is a length difference of the third length L3 and the second length L2. The length difference LD2 may be defined by an up-and-down directional height difference between the upper end 234 of the grounding conduction portion and the upper end 214 of the signal conduction portion. The length difference LD1 and the length difference LD2 may have an equal numerical value or an approximately equal numerical value.

In the portion of the connector shown in FIG. 2, the first length L1 of the electric power conduction portion and the third length L3 of the grounding conduction portion are longer than the second length L2 of the signal conduction portion, and the length difference LD1 and the length difference LD2 are formed in the up-and-down direction on the upper surface of the housing 100. Therefore, in the non-pressed state, the upper end 214 of the signal conduction portion is positioned below the upper end 224 of the electric power conduction portion by the length difference LD1, and is positioned below the upper end 234 of the grounding conduction portion by the length difference LD2. Thus, the electric power conduction portion 220 and the grounding conduction portion 230 located adjacent to the signal conduction portion 210 protrude more upward than the signal conduction portion 210. Regarding the length differences between different conduction portions, in the non-pressed state, the second length L2 of the signal conduction portion is shorter than the first length L1 by the length difference LD1, and the length difference LD1 may be equal to 5% to 15% of the first length L1. When assuming the length of the electric power conduction portion in the non-pressed state as 1, a ratio of the length of the electric power conduction portion to the length of the signal conduction portion may be in a range of 1:0.85 to 1:0.95.

In the non-pressed state, the length differences are formed in the up-and-down direction between the upper ends of the electric power conduction portion and the grounding conduction portion and the upper end of the signal conduction portion. Therefore, during testing of the device under test, the terminals of the device under test do not simultaneously come in contact with the upper ends of the respective conduction portions. The electric power terminal of the device under test can first come in contact with the upper end 224 of the electric power conduction portion, and, thereafter, the signal terminal of the device under test can come in contact with the upper end 214 of the signal conduction portion. Thus, the electric power conduction portion 220 (or the electric power conduction portion and the grounding conduction portion) can be first compressed in the up-and-down direction VD before the signal conduction portion 210 is compressed.

The electric power conduction portion 220 and the grounding conduction portion 230 have a diameter greater than a diameter of the signal conduction portion 210. In this regard, the diameter may mean a width of each conduction portion in the horizontal direction HD. Cross-sectional areas of the respective through holes of the housing 100 may be the same. The signal conduction portion 210 may have a small diameter such that a spaced distance between the inner peripheral surface of the through hole of the housing and the outer peripheral surface of the signal conduction portion is large, and the signal conduction portion can show a high signal transmission property. The electric power conduction portion 220 and the grounding conduction portion 230 may have a diameter greater than the diameter of the signal conduction portion such that a sufficient amount of electric current can flow through the electric power conduction portion and the grounding conduction portion.

Regarding the signal conduction portion 210 disposed in the first through hole, a dielectric permittivity of a portion surrounding the signal conduction portion 210 may affect the signal transmission property and the impedance matching of the signal conduction portion. If such a portion has a low dielectric permittivity, the signal conduction portion 210 can have reduced signal loss, and the impedance of the signal conduction portion can be better matched with an impedance of the device under test and an impedance of the testing circuit of the test apparatus. According to one embodiment of the connector, the insulation space 113 within the first through hole surrounds the signal conduction portion 210. The insulation space 113 is filled with air having a dielectric permittivity of about 1. Accordingly, the insulation space 113 surrounding the signal conduction portion 210 in the circumferential direction of the central axis CA1 has a very low dielectric permittivity. Thus, the signal conduction portion 210 can have a reduced signal loss and an improved high frequency property, and can exhibit better impedance matching.

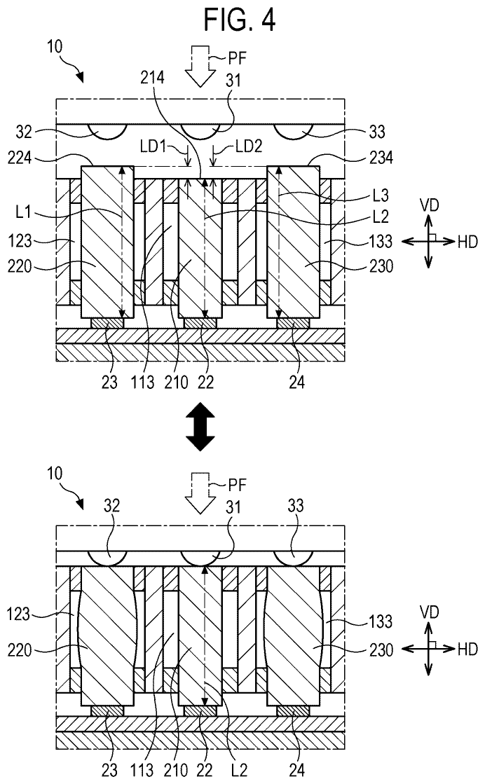

FIG. 4 is a sectional view schematically showing the non-pressed state and the pressed state of each conduction portion in the portion of the connector shown in FIG. 2. Descriptions are made regarding the deformation of each conduction portion and the operation of the portion of the connector with reference to FIGS. 2 and 4.

As the device under test is pressed downward by the pressing force PF, each conduction portion changes from the non-pressed state illustrated at an upper side of FIG. 4 to the pressed state illustrated a lower side of FIG. 4. Due to the length differences LD1 and LD2, the upper end 224 of the electric power conduction portion and the upper end 234 of the grounding conduction portion protrude more upward than the upper end 214 of the signal conduction portion. The electric power terminal 32 and the grounding terminal 33 of the device under test first come in contact with the electric power conduction portion 220 and the grounding conduction portion 230.

As the device under test continues to be pressed by the pressing force PF, the electric power conduction portion 220 and the grounding conduction portion 230 are compressed in the up-and-down direction before the signal conduction portion 210 is compressed. Therefore, the first length L1 of the electric power conduction portion and the third length L3 of the grounding conduction portion are decreased, and the length differences LD1 and LD2 are decreased. While the electric power conduction portion 220 and the grounding conduction portion 230 pressed by the electric power terminal 32 and the grounding terminal 33, respectively, start to be elastically deformed and are compressed in the up-and-down direction to a predetermined extent, the signal terminal 31 does not come in contact with the upper end of the signal conduction portion 210.

As the length differences LD1 and LD2 are decreased to a predetermined extent by the pressing force PF, the signal terminal 31 comes in contact slightly with the upper end of the signal conduction portion 210, or the signal terminal 31 and the upper end of the signal conduction portion 210 approach each other by a minute distance. Further, the device under test may be stopped in the state of receiving the pressing force PF without further downward movement. In a state where the electric power conduction portion 220 and the grounding conduction portion 230 are first compressed and elastically deformed to a predetermined extent and the signal conduction portion 210 comes in contact slightly with or approaches the signal terminal 31 by the minute distance, as described above, the test signals and the response signals are transmitted through the signal conduction portion 210. The electric power conduction portion 220 and the grounding conduction portion 230 are pressed prior to the signal conduction portion 210 and resist against the pressing force PF. Further, in the state where the signal conduction portion 210 comes in contact slightly with the signal terminal 31 or approaches the signal terminal by a minute distance without any contact therebetween, the testing of the device under test pressed by the pressing force can be performed.

In the pressed state where the electric power conduction portion 220 and the grounding conduction portion 230 are deformed prior to the signal conduction portion 210 and the signal conduction portion 210 is hardly pressed, the testing of the device under test can be performed. Therefore, in the pressed state during testing of the device under test, a reference load can be applied to the device under test. Accordingly, a contact strength between the signal terminal 31 of the device under test and the signal conduction portion 210 can be reduced, and the damage of the signal terminal 31 and the signal conduction portion 210 can be prevented. In this regard, the reference load means the pressing force PF that is applied to the device under test so as to exhibit a low reference resistance value required for testing of the device under test.

Further, the electric power conduction portion 220 and the grounding conduction portion 230 can be operated so as to exhibit an appropriate stroke. In this regard, the appropriate stroke means a length at which the conduction portion can be elastically pressed and elastically restored so that contact numbers and contact areas of the conductive particles in the elastic substance can be increased to reduce the resistance of the conduction portion.

Further, since the signal conduction portion 210 is hardly pressed, the signal conduction portion does not have a change in its shape. Therefore, the spaced distance between the inner peripheral surface of the first through hole 110 and the outer peripheral surface of the signal conduction portion 210 can be maintained constantly from the vicinity of the lower end of the signal conduction portion to the vicinity of the upper end of the signal conduction portion. In addition, the shape of the insulation space 113, which surrounds the signal conduction portion 210 and is filled with air, can be maintained constantly during the testing of the device under test. Accordingly, the signal conduction portion 210 can prevent signal loss, can show improved test reliability, and can achieve better impedance matching.

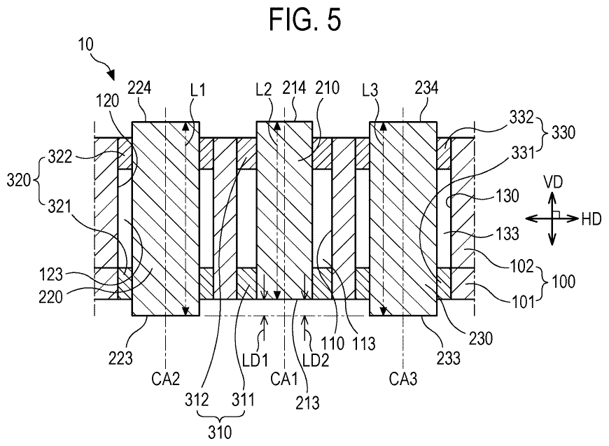

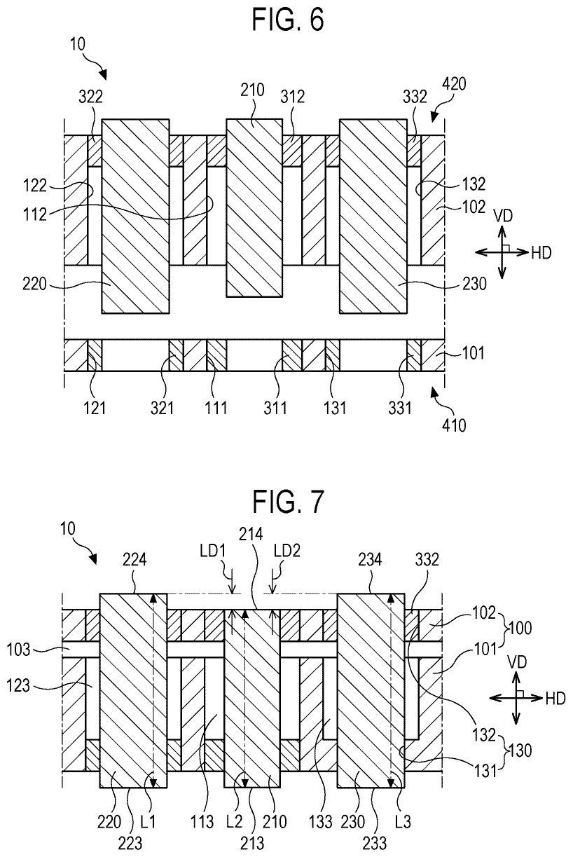

Reference is made to FIG. 5 showing a portion of a connector according to a second embodiment of the present disclosure and FIG. 6 schematically showing a disassembled state of the portion of the connector shown in FIG. 5. The connector according to the embodiment shown in FIGS. 5 and 6 has a configuration similar to the configuration of the connector according to the above-described first embodiment, except that the length differences are formed under the lower surface of the housing.

FIG. 5 illustrates a non-pressed state of each conduction portion. In the non-pressed state, the length difference LD1 and the length difference LD2 are formed under the lower surface of the housing 100. The upper end 214 of the signal conduction portion, the upper end 224 of the electric power conduction portion, and the upper end 234 of the grounding conduction portion are positioned at the same level. The lower end 213 of the signal conduction portion is positioned above the lower end 223 of the electric power conduction portion by the length difference LD1, and is positioned above the lower end 233 of the grounding conduction portion by the length difference LD2. Therefore, the length difference LD1 is defined by an up-and-down directional height difference between the lower end 223 of the electric power conduction portion and the lower end 213 of the signal conduction portion, and the length difference LD2 is defined by an up-and-down directional height difference between the lower end 233 of the grounding conduction portion and the lower end 213 of the signal conduction portion.

When the pressing force presses the device under test to the connector 10, or when the pressing force is applied to the connector 10, the signal terminal, the electric power terminal, and the grounding terminal of the device under test can simultaneously come in contact with the upper end 214 of the signal conduction portion, the upper end 224 of the electric power conduction portion, and the upper end 234 of the grounding conduction portion. The length differences LD1 and LD2 are formed at the lower surface of the housing, and the lower end 213 of the signal conduction portion is positioned above the lower end 213 of the electric power conduction portion and the lower end 233 of the grounding conduction portion. Thus, before the signal conduction portion 210 is compressed, the electric power conduction portion 220 and the grounding conduction portion 230 are first compressed in the up-and-down direction. Therefore, the first length L1 of the electric power conduction portion and the third length L3 of the grounding conduction portion are decreased, and the length differences LD1 and LD2 are decreased. While the electric power conduction portion 220 and the grounding conduction portion 230 pressed by the electric power terminal and the grounding terminal, respectively, start to be elastically deformed and are compressed in the up-and-down direction to a predetermined extent, the signal conduction portion 210 is not compressed.

After the electric power conduction portion 220 and the grounding conduction portion 230 are compressed while resisting the pressing force and the length differences LD1 and LD2 are decreased to a predetermined extent, the signal conduction portion 210 can come in contact with the pad of the test apparatus. In such a state, the device under test may be stopped in the state of receiving the pressing force PF without further downward movement. In the pressed state where the electric power conduction portion 220 and the grounding conduction portion 230 are first compressed and elastically deformed to a predetermined extent and the signal conduction portion 210 is hardly deformed, as described above, the test signals and the response signals are transmitted through the signal conduction portion 210. Accordingly, in the pressed state, the signal conduction portion does not have a shape change, and the spaced distance between the inner peripheral surface of the first through hole 110 and the outer peripheral surface of the signal conduction portion 210 can be maintained constantly from the vicinity of the lower end of the signal conduction portion to the vicinity of the upper end of the signal conduction portion.

Referring to FIG. 6, according to one embodiment of the connector, the connector 10 may be manufactured by assembly of a lower module 410 and an upper module 420. A portion of the elements of the connector is modularized into the lower module 410, and the remainder of the elements of the connector is modularized into the upper module 420.

The first housing 101 has a first lower through hole 111 becoming a portion of the first through hole, a second lower through hole 121 becoming a portion of the second through hole, and a third lower through hole 131 becoming a portion of the third through hole. The first lower insulation portion 311 is disposed in the first lower through hole 111, the second lower insulation portion 321 is disposed in the second lower through hole 121, and the third lower insulation portion 331 is disposed in the third lower through hole 131. The first housing 101, the first lower insulation portion 311, the second lower insulation portion 321, and the third lower insulation portion 331 are formed integrally, thereby constituting the lower module 410. By way of example, the lower module 410 may be manufactured by filling each of the lower through holes 111, 121, and 131 of the first housing 101 with an insulating material constituting the lower insulation portion and then forming a through hole in the filled insulating material in the up-and-down direction to form the lower insulation portion.

The second housing 102 has a first upper through hole 112 becoming the remainder of the first through hole, a second upper through hole 122 becoming the remainder of the second through hole, and a third upper through hole 132 becoming the remainder of the third through hole. The first upper insulation portion 312 is disposed in the first upper through hole 112, the second upper insulation portion 322 is disposed in the second upper through hole 122, and the third upper insulation portion 332 is disposed in the third upper through hole 132. The signal conduction portion 210 may be integrally formed with the first upper insulation portion 312, the electric power conduction portion 220 may be integrally formed with the second upper insulation portion 322, and the grounding conduction portion 230 may be integrally formed with the third upper insulation portion 332. The second housing 102, the signal conduction portion 210, the first upper insulation portion 312, the electric power conduction portion 220, the second upper insulation portion 322, the grounding conduction portion 230, and the third upper insulation portion 332 are formed integrally, thereby constituting the upper module 420.

By way of example, the upper module 420 may be manufactured by using the second housing 102 with the upper through holes formed therein, a molding die, and a liquid molding material. The liquid molding material includes a liquid substance of the elastic substance of each conduction portion, and a multiple number of conductive particles dispersed in the liquid substance. The molding die has a molding cavity corresponding to each upper through hole of the second housing, and the liquid molding material is injected into the molding cavity. As a magnetic field is applied to the liquid molding material injected into the molding cavity in the up-and-down direction, a multiple number of conductive particles are grouped together in the up-and-down direction by the magnetic field. Thereafter, the elastic substance in the liquid molding material is hardened. Therefore, each conduction portion and each upper insulation portion are formed integrally in each upper through hole of the second housing. The molding cavity for molding the signal conduction portion 210 may have a length shorter than the molding cavity for molding the electric power conduction portion 220 and the grounding conduction portion 230 by the above-described length difference. Thus, the signal conduction portion having the second length shorter than the first length or the third length by the above-described length difference can be molded.

The first housing 101 of the lower module 410 and the second housing 102 of the upper module 420 may be coupled by bonding. As the first housing 101 and the second housing 102 are coupled, the conduction portions 210, 220, and 230 may be respectively fitted or inserted into the lower insulation portions 311, 321, and 331 corresponding thereto. Further, as the first housing 101 and the second housing 102 are coupled, the first lower through hole 111 and the first upper through hole 112 form the first through hole 110, the second lower through hole 121 and the second upper through hole 122 form the second through hole 120, and the third lower through hole 131 and the third upper through hole 132 form the third through hole 130.

Since the lower module 410 and the upper module 420 are coupled, the connector 10, in which the above-described length differences are provided to the electric power conduction portion 220, the signal conduction portion 210, and the grounding conduction portion 230, can be manufactured. One example of the manufacturing method of the connector described with reference to FIG. 6 may be applied to manufacturing the connector described with reference to FIG. 2, or to manufacturing a connector according to the embodiments described below.

Reference is made to FIG. 7 showing a portion of a connector according to a third embodiment of the present disclosure. The connector according to the embodiment shown in FIG. 7 has a configuration similar to the configuration of the connector according to the above-described first embodiment, except that the first and second housings constituting the housing are separated from each other.

In the connector 10 shown in FIG. 7, the third insulation portion supporting the grounding conduction portion 230 includes only the third upper insulation portion 332 disposed in the third upper through hole 132. Further, the grounding conduction portion 230 is disposed so as to be electrically connected to the first housing 101 of the housing through the third through hole 130. By way of example, the third lower through hole 131 forming a portion of the third through hole has an inner diameter smaller than an inner diameter of the third upper through hole 132. The conductive particles of the grounding conduction portion 230 come in contact conductively with an inner peripheral surface of the third lower through hole 131, thereby electrically connecting the grounding conduction portion 230 to the first housing 101. As another example, the above-described third lower insulation portion may be disposed in the third lower through hole.

The second length L2 of the signal conduction portion is shorter than the first length L1 of the electric power conduction portion by the length difference LD1, and is shorter than the third length L3 of the grounding conduction portion by the length difference LD2. The length differences LD1 and LD2 are formed on the upper surface of the second housing 102, and the upper end 224 of the electric power conduction portion and the upper end 234 of the grounding conduction portion protrude more upward than the upper end 214 of the signal conduction portion. In the non-pressed state shown in FIG. 7, the length difference LD1 is formed between the upper end 224 of the electric power conduction portion and the upper end 214 of the signal conduction portion in the up-and-down direction, and the length difference LD2 is formed between the upper end 234 of the grounding conduction portion and the upper end 214 of the signal conduction portion in the up-and-down direction.

The connector 10 shown in FIG. 7 includes the housing 100 consisting of the first and second housings 101 and 102, which are disposed up and down and are stacked into a two-layer structure. The second housing 102 is spaced apart upward from the first housing 101, and has a length shorter than an up-and-down directional length of the first housing 101.

The first and second housings 101 and 102 spaced apart in the up-and-down direction form an air layer 103 therebetween. The insulation spaces 113, 123, and 133 surrounding the respective conduction portions communicate with the air layer 103. The first housing 101 may be mounted to the above-described socket guide. The second housing 102 may be supported with respect to the first housing 101 by the signal conduction portion 210, the electric power conduction portion 220, and the grounding conduction portion 230. The second housing 102 may be supported with respect to the first housing 101 by the signal conduction portion 210, the first upper insulation portion 312, the electric power conduction portion 220, the second upper insulation portion 322, the grounding conduction portion 230, and the third upper insulation portion 332 in the state of being spaced apart upward from or floating above the first housing 101.

By way of example, the second housing 102 may be integrally formed with at least one or more of a combination of the signal conduction portion and the first upper insulation portion, a combination of the electric power conduction portion and the second upper insulation portion, and a combination of the grounding conduction portion and the third upper insulation portion. By coupling the second housing 102 integrally formed with the conduction portions as described above to the first housing 101, the second housing 102 can be connected to the first housing 101. Therefore, the housing 100, which has a short up-and-down directional length and in which the conduction portions are disposed, can be manufactured.

Since the second housing 102 can be resiliently supported with respect to the first housing 101, the connector 10 can exhibit improved operability. The signal terminal, the electric power terminal, and the grounding terminal of the device under test do not have the same height, but can have minute height differences, and the lower ends of the signal terminal, the electric power terminal, and the grounding terminal may not be positioned at the same level. The second housing 102 is resiliently supported with respect to the first housing 101, and the upper end of the electric power conduction portion 220 and the upper end of the grounding conduction portion 230 have the length differences LD1 and LD2 and protrude more upward than the upper end of the signal conduction portion 210. Therefore, when the device under test comes in contact with the connector 10, the second housing 102 can cope with the height differences of the terminals of the device under test. When the terminal having a relatively large height first comes in contact with the electric power conduction portion 220 or the grounding conduction portion 230, the second housing 102 can absorb the height difference and can allow the electric power terminal or the grounding terminal of the device under test to smoothly come in contact with the electric power conduction portion 220 or the grounding conduction portion 230 without a deformation of the signal conduction portion 210. Further, where the terminal of the device under test presses the conduction portion and the second housing 102 in a state of being offset from a center of the conduction portion, the second housing 102 is resiliently supported and the pressing force can be absorbed or distributed. Therefore, where the terminal of the device under test and the center of the conduction portion are offset, the terminal of the device under test can be prevented from being damaged by the metallic housing.

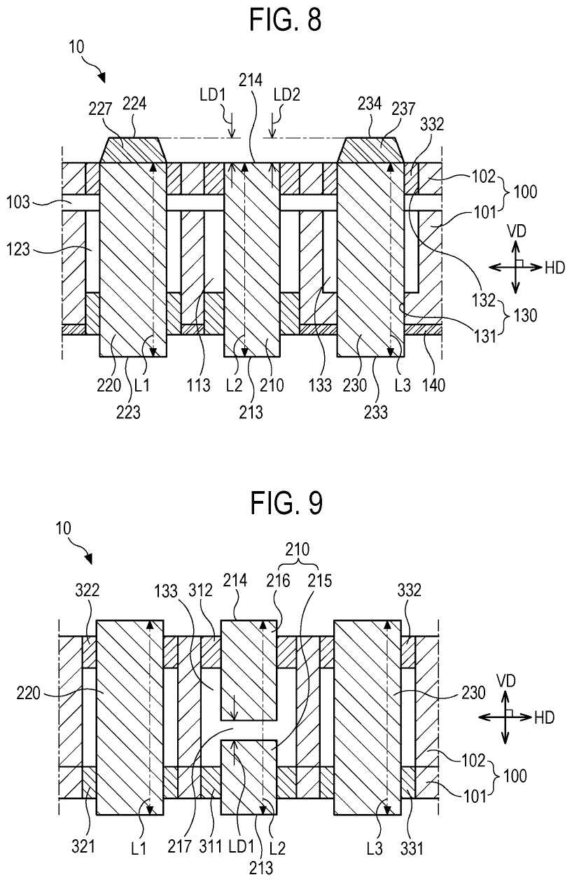

Reference is made to FIG. 8 showing a portion of a connector according to a fourth embodiment of the present disclosure. The connector according to the embodiment shown in FIG. 8 has a configuration similar to the configuration of the connector according to the above-described first and third embodiments, except that the electric power conduction portion and the grounding conduction portion include a protruding conduction portion.

In the connector 10 shown in FIG. 8, the above-described length differences LD1 and LD2 may be formed by protruding conduction portions 227 and 237 formed at an upper end portion of the electric power conduction portion 220 and an upper end portion of the grounding conduction portion 230.

The electric power conduction portion 220 includes a first protruding conduction portion 227 forming the upper end portion of the electric power conduction portion, and the grounding conduction portion 230 includes a second protruding conduction portion 237 forming the upper end portion of the grounding conduction portion. The first protruding conduction portion 227 protrudes more upward than the upper end 214 of the signal conduction portion, and has an up-and-down directional length corresponding to the length difference LD1. An upper end of the first protruding conduction portion 227 forms the upper end 224 of the electric power conduction portion. The second protruding conduction portion 237 protrudes more upward than the upper end 214 of the signal conduction portion, and has an up-and-down directional length corresponding to the length difference LD2. An upper end of the second protruding conduction portion 237 forms the upper end 234 of the grounding conduction portion. Each of the protruding conduction portions 227 and 237 may have a truncated cone shape or a circular column shape. Each of the protruding conduction portions 227 and 237 may be applied to the connector described with reference to FIG. 2.

Each of the protruding conduction portions 227 and 237 may be made of conductive particles and elastic substance, similarly to the configuration of the above-described conduction portion. In such a case, after the signal conduction portion 210 is molded so as to have the second length L2, the first protruding conduction portion 227 may be formed on the upper end of the electric power conduction portion and the second protruding conduction portion 237 may be formed on the upper end of the grounding conduction portion. By way of example, in a state where the electric power conduction portion 220 and the grounding conduction portion 230 are molded so as to have an upper end positioned at the same level as the upper end 214 of the signal conduction portion, a molding die with molding holes corresponding to the electric power conduction portion and the grounding conduction portion formed therein may be disposed on the upper surface of the second housing 102. A liquid molding material, in which the conductive particles and the liquid elastic substance are mixed, is injected into the molding holes, and then the conductive particles are grouped together in the up-and-down direction by application of a magnetic field. Therefore, each of the protruding conduction portions 227 and 237 may form the upper end portion of the corresponding conduction portion. As another example, each of the protruding conduction portions 227 and 237 may be made of one conductive metallic member, and may be conductively attached to the electric power conduction portion 220 or the grounding conduction portion 230.

In the connector shown in FIG. 8, the housing 100 may include a support film 140 that is attached to the lower surface of the first housing 101. The support film 140 may be made of polyimide resin. The support film 140 may have through holes corresponding to the respective through holes of the housing, and each insulation portion may be coupled to the through hole of the support film 140.

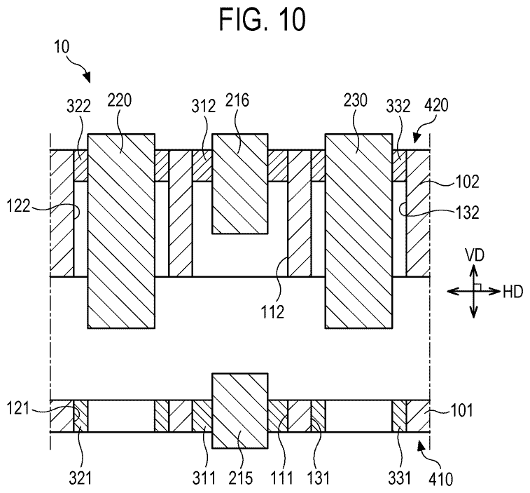

Reference is made to FIG. 9 showing a portion of a connector according to a fifth embodiment of the present disclosure and FIG. 10 schematically showing a disassembled state of the portion of the connector shown in FIG. 9. The connector according to the embodiment shown in FIGS. 9 and 10 has a configuration similar to the configuration of the connector according to the above-described first embodiment, except that the length difference is formed between two separated portions of the signal conduction portion.

FIG. 9 illustrates a non-pressed state of each conduction portion. In the non-pressed state, the signal conduction portion 210 includes a lower signal conduction portion 215 and an upper signal conduction portion 216, which are separated in the up-and-down direction VD. The lower signal conduction portion 215 is coupled to the first lower insulation portion 311. The upper signal conduction portion 216 is coupled to the first upper insulation portion 312, and is spaced apart upward from the lower signal conduction portion 215 by a predetermined gap in the non-pressed state. When the signal conduction portion 210 changes from the non-pressed state to the pressed state, the aforesaid predetermined gap is reduced and eliminated by the pressing force. In the pressed state of the signal conduction portion 210, the aforesaid predetermined gap is completely eliminated, and the upper signal conduction portion 216 conductively comes in contact with the lower signal conduction portion 215 in the up-and-down direction VD. Hereinafter, the aforesaid predetermined gap is referred to as a switch gap 217. The switch gap 217 communicates with the insulation space 133.

In the non-pressed state, an up-and-down directional length of the switch gap 217 may be equal to the dimension of the above-described length difference LD1. Thus, the up-and-down directional length of the switch gap 217 may have a dimension equal to 5% to 15% of the first length L1 of the electric power conduction portion. The length difference LD1 is positioned within the first through hole 110, and may be defined by an up-and-down directional spaced distance between the separated, lower signal conduction portion 215 and upper signal conduction portion 216 of the signal conduction portion. The second length L2 of the signal conduction portion 210 may be defined by the up-and-down directional distance between the lower end 213 and the upper end 214 of the signal conduction portion, and excludes the up-and-down directional distance of the switch gap 217.

FIG. 9 shows that the switch gap 217 is positioned at the middle of the signal conduction portion 210, but the switch gap 217 may be positioned at a position close to the upper end 214 of the signal conduction portion or at a position close to the lower end 213 of the signal conduction portion. Accordingly, up-and-down directional lengths of the lower signal conduction portion 215 and the upper signal conduction portion 216 may be different from each other.

Referring to FIG. 10, the lower signal conduction portion 215 is formed integrally with the first lower insulation portion 311, and the second lower insulation portion 321 and the third lower insulation portion 331 are formed integrally with the second lower through hole 121 and the third lower through hole 131, thereby constituting the lower module 410. The upper signal conduction portion 216 is formed integrally with the first upper insulation portion 312, the electric power conduction portion 220 is formed integrally with the second upper insulation portion 322, and the grounding conduction portion 230 is formed integrally with the third upper insulation portion 332, thereby constituting the upper module 420. When molding the lower module 410, the lower signal conduction portion 215 may be molded together with the first lower insulation portion 311 by the molding method using the above-described liquid molding material. When molding the lower module 410 and the upper module 420, the lower signal conduction portion 215 and the upper signal conduction portion 216 are molded so as to have an up-and-down directional length for forming the above-described switch gap therebetween. For example, a sum of the up-and-down directional length of the lower signal conduction portion 215 of the lower module 410 and the up-and-down directional length of the upper signal conduction portion 216 of the upper module 420 may be less than the first length of the electric power conduction portion 220 by a numerical value of 5% to 15% of the first length.

The first housing 101 of the lower module 410 and the second housing 102 of the upper module 420, which are manufactured individually, may be coupled by bonding. As the first housing 101 and the second housing 102 are coupled, the electric power conduction portion 220 can be inserted into the second lower insulation portion 321 and the grounding conduction portion 230 can be inserted into the third lower insulation portion 331. As the lower module 410 and the upper module 420 are coupled, the connector, in which the length difference LD1 is formed in the signal conduction portion 210 within the first through hole 110, can be manufactured.

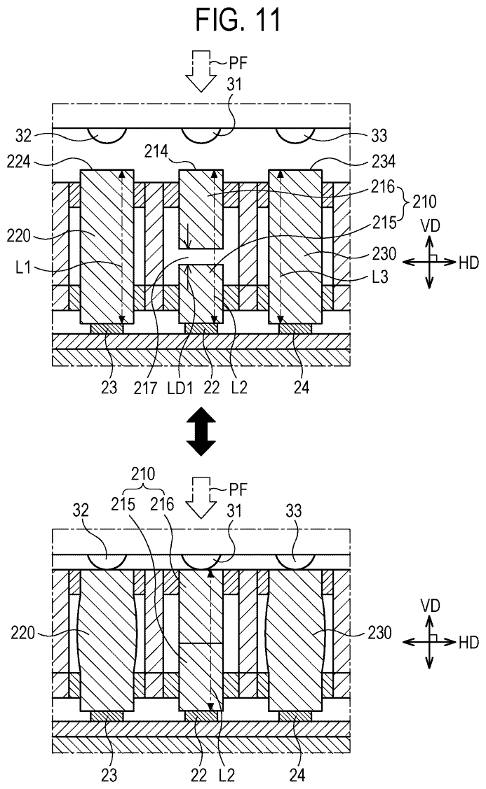

FIG. 11 is a sectional view schematically showing the non-pressed state and the pressed state of each conduction portion in the portion of the connector shown in FIG. 9. Descriptions are made regarding the deformation of each conduction portion and the operation of the portion of the connector under the pressing force with reference to FIGS. 9 and 11.

The signal terminal 31, the electric power terminal 32, and the grounding terminal 33 of the device under test can simultaneously come in contact with the upper end 214 of the signal conduction portion (the upper end of the upper signal conduction portion), the upper end 224 of the electric power conduction portion, and the upper end 234 of the grounding conduction portion by the pressing force PF. Since the switch gap 217 having the length difference LD1 is formed between the lower signal conduction portion 215 and the upper signal conduction portion 216 and the lower signal conduction portion 215 and the upper signal conduction portion 216 are spaced apart by the switch gap 217, the electric power conduction portion 220 and the grounding conduction portion 230 are first compressed in the up-and-down direction before the signal conduction portion 210 is compressed. Therefore, the first length L1 of the electric power conduction portion and the third length L3 of the grounding conduction portion are decreased, and the switch gap 217 having the length difference LD1 is reduced.

As the device under test continues to be pressed downward by the pressing force PF and the switch gap 217 having the length difference LD1 is eliminated between the upper signal conduction portion 216 and the lower signal conduction portion 215, the signal conduction portion 210 is brought into the pressed state, and is brought into the state of being conductive in the up-and-down direction VD. Further, the device under test may be stopped in the state of receiving the pressing force PF without further downward movement. In the state where the electric power conduction portion 220 and the grounding conduction portion 230 are first compressed and elastically deformed to a predetermined extent and the switch gap 217 having the length difference LD1 is eliminated, as described above, the test signals and the response signals are transmitted through the signal conduction portion 210. Accordingly, in the pressed state, the signal conduction portion 210 does not have a shape change, and the spaced distance between the inner peripheral surface of the first through hole 110 and the outer peripheral surface of the signal conduction portion 210 can be maintained constantly from the vicinity of the lower end of the signal conduction portion to the vicinity of the upper end of the signal conduction portion.

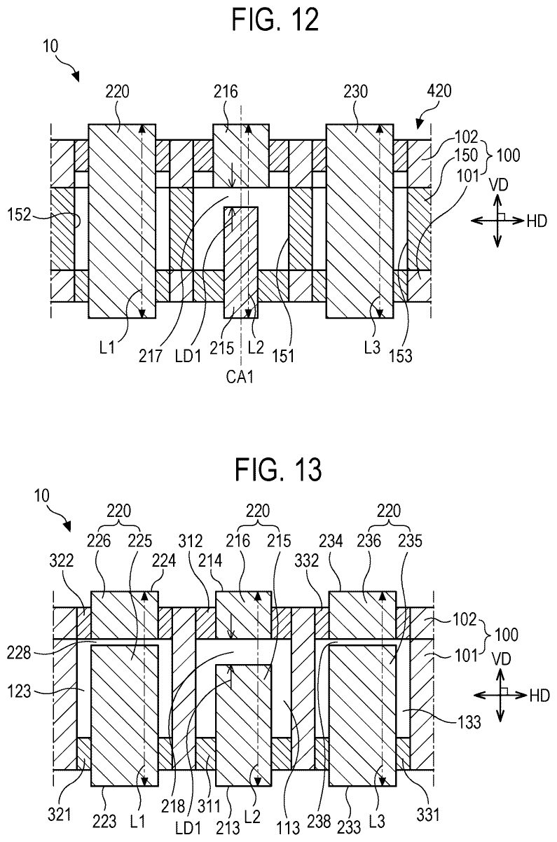

Reference is made to FIG. 12 showing a portion of a connector according to a sixth embodiment of the present disclosure. The connector according to the embodiment shown in FIG. 12 has a configuration similar to the configuration of the connector according to the above-described fifth embodiment, except that the upper and lower signal conduction portions have a different diameter and an elastic insulation housing is disposed between the first and second housings.

The second housing 102 of the housing 100 is formed so as to have an up-and-down directional length shorter than the second housing according to the above-described embodiment, thereby constituting the upper module 420. The housing 100 includes an elastic insulation housing 150 disposed between the first housing 101 and the second housing 102. The elastic insulation housing 150 has an insertion hole 151 becoming a portion of the first upper through hole, an insertion hole 152 becoming a portion of the second upper through hole, and an insertion hole 153 becoming a portion of the third upper through hole. The elastic insulation housing 150 is stacked on the first housing 101, the second housing 102 is stacked on the elastic insulation housing 150, and the elastic insulation housing 150 and the first and second housings may be coupled by bonding. The electric power conduction portion 220 and the grounding conduction portion 230 are inserted into the insertion holes 152 and 153 of the elastic insulation housing, respectively, and the lower signal conduction portion 215 is inserted into the insertion hole 151 of the elastic insulation housing.

When the second housing 102 is pressed by the pressing force, the elastic insulation housing 150 can resiliently support the second housing 102 with respect to the first housing 101, and the elastic insulation housing 150 can absorb and distribute the pressing force by its elastic force. For example, when the terminal of the device under test presses the conduction portion and the second housing 102 in the state of being offset from a center of the conduction portion, the second housing 102 is resiliently supported by the elastic insulation housing 150 and the pressing force can be absorbed or distributed. Therefore, where the terminal of the device under test and the center of the conduction portion are offset, the terminal of the device under test can be prevented from being damaged by the metallic housing, and the connector can have good operability.

The lower signal conduction portion 215 and the upper signal conduction portion 216 may have a diameter different from each other. In the example shown in FIG. 12, the lower signal conduction portion 215, which is spaced apart downward from the upper signal conduction portion 216 by the switch gap 217, is formed so as to have a diameter less than a diameter of the upper signal conduction portion 216. The first lower insulation portion 311 has a size greater than the first upper insulation portion 312, and positions the lower signal conduction portion 215 coaxially with the central axis CA1 of the first through hole. Thus, the insulation space 113 may consist of an upper portion surrounding the upper signal conduction portion 216, and a lower portion having a size greater than the upper portion and surrounding the lower signal conduction portion 215. Since the lower signal conduction portion 215 and the upper signal conduction portion 216 have a diameter different from each other and the switch gap 217 having the length difference LD1 is formed in the signal conduction portion, the shape and diameter of the signal conduction portion can vary for impedance matching in accordance with a dielectric permittivity of the housing or the material constituting the first insulation portion.

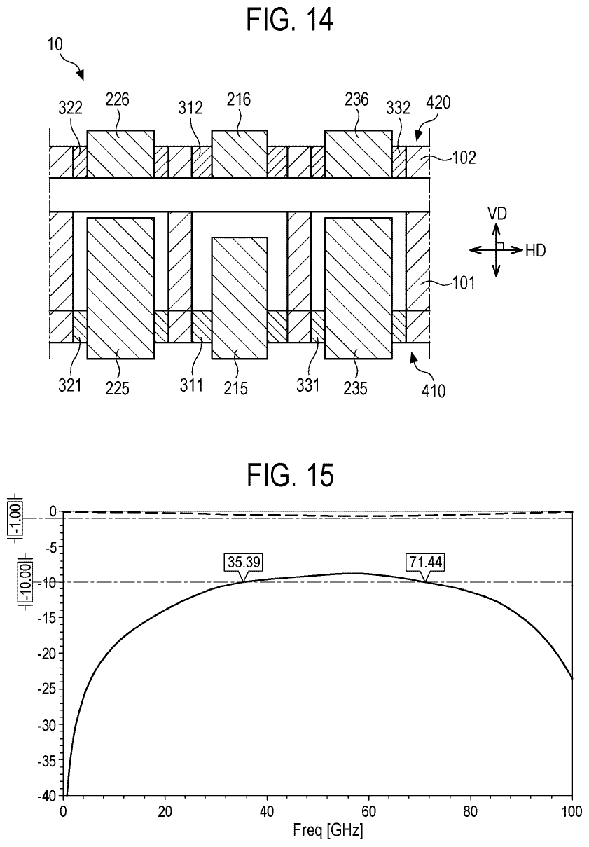

Reference is made to FIG. 13 showing a portion of a connector according to a seventh embodiment of the present disclosure and FIG. 14 schematically showing a disassembled state of the portion of the connector shown in FIG. 13. The connector according to the embodiment shown in FIGS. 13 and 14 has a configuration similar to the configuration of the connector according to the above-described first and sixth embodiments, except that each conduction portion consists of two separated portions.

FIG. 13 illustrates a non-pressed state of each conduction portion. In the non-pressed state, the signal conduction portion 210 includes the lower signal conduction portion 215 and the upper signal conduction portion 216, which are separated in the up-and-down direction VD. The lower signal conduction portion 215 is coupled to the first lower insulation portion 311. The upper signal conduction portion 216 is coupled to the first upper insulation portion 312, and, in the non-pressed state, is spaced apart upward from the lower signal conduction portion 215 by a first switch gap 218. When the signal conduction portion 210 changes from the non-pressed state into the pressed state, the first switch gap 218 communicating with the insulation space 113 is reduced and eliminated by the pressing force. In the pressed state of the signal conduction portion 210, the first switch gap 218 is completely eliminated, and therefore, the upper signal conduction portion 216 conductively comes in contact with the lower signal conduction portion 215 in the up-and-down direction VD.

In the non-pressed state, the electric power conduction portion 220 includes a lower electric power conduction portion 225 and an upper electric power conduction portion 226, which are separated in the up-and-down direction VD. The lower electric power conduction portion 225 is coupled to the second lower insulation portion 321. The upper electric power conduction portion 226 is coupled to the second upper insulation portion 322, and, in the non-pressed state, is spaced apart upward from the lower electric power conduction portion 225 by a second switch gap 228. When the electric power conduction portion 220 changes from the non-pressed state into the pressed state, the second switch gap 228 communicating with the insulation space 123 is reduced and eliminated by the pressing force. In the pressed state of the electric power conduction portion 220, the second switch gap 228 is completely eliminated, and therefore, the upper electric power conduction portion 226 conductively comes in contact with the lower electric power conduction portion 225 in the up-and-down direction VD.

In the non-pressed state, the grounding conduction portion 230 includes a lower grounding conduction portion 235 and an upper grounding conduction portion 236, which are separated in the up-and-down direction VD. The lower grounding conduction portion 235 is coupled to the third lower insulation portion 331. The upper grounding conduction portion 236 is coupled to the third upper insulation portion 332, and, in the non-pressed state, is spaced apart upward from the lower grounding conduction portion 235 by a third switch gap 238. When the grounding conduction portion 230 changes from the non-pressed state into the pressed state, the third switch gap 238 communicating with the insulation space 133 is reduced and eliminated by the pressing force. In the pressed state of the grounding conduction portion 230, the third switch gap 238 is completely eliminated, and therefore, the upper grounding conduction portion 236 conductively comes in contact with the lower grounding conduction portion 235 in the up-and-down direction VD.

In the non-pressed state, an up-and-down directional length of the first switch gap 218 may be a sum of an up-and-down directional length of the second switch gap 228 and the dimension of the above-described length difference LD1. Thus, the up-and-down directional length of the first switch gap 218 may be a sum of the numerical value equal to 5% to 15% of the first length L1 of the electric power conduction portion and the up-and-down directional length of the second switch gap 228. The length difference LD1 is positioned inside the first through hole 110, and may be defined by an up-and-down directional spaced distance between the separated, lower signal conduction portion 215 and upper signal conduction portion 216 of the signal conduction portion. The second switch gap 228 of the electric power conduction portion and the third switch gap 238 of the grounding conduction portion may have an equal numerical value or an approximately equal numerical value.

In the embodiment shown in FIG. 13, the second length L2 of the signal conduction portion 210 may be defined by an up-and-down directional distance between the lower end 213 of the signal conduction portion (the lower end of the lower signal conduction portion) and the upper end 214 of the signal conduction portion (the upper end of the upper signal conduction portion) in the non-pressed state, and excludes the up-and-down directional distance of the first switch gap 218. In the embodiment shown in FIG. 13, the first length L1 of the electric power conduction portion may be defined by an up-and-down directional distance between the lower end 223 of the electric power conduction portion (the lower end of the lower electric power conduction portion) and the upper end 224 of the electric power conduction portion (the upper end of the upper electric power conduction portion) in the non-pressed state, and excludes the up-and-down directional distance of the second switch gap 228. In the embodiment shown in FIG. 13, the third length L3 of the grounding conduction portion may be defined by an up-and-down directional distance between the lower end 233 of the grounding conduction portion (the lower end of the lower grounding conduction portion) and the upper end 234 of the grounding conduction portion (the upper end of the upper grounding conduction portion) in the non-pressed state, and excludes the up-and-down directional distance of the third switch gap 238.

The signal terminal, the electric power terminal, and the grounding terminal of the device under test can simultaneously come in contact with the upper end 214 of the signal conduction portion (the upper end of the upper signal conduction portion), the upper end 224 of the electric power conduction portion (the upper end of the upper electric power conduction portion), and the upper end 234 of the grounding conduction portion (the upper end of the upper grounding conduction portion) by the pressing force. Since the first switch gap 218 having the length difference LD1 is formed in the signal conduction portion 210, the lower electric power conduction portion 225 and the upper electric power conduction portion 226 come into contact first and can be compressed by the pressing force before the lower signal conduction portion 215 and the upper signal conduction portion 216 come into contact. Further, the lower grounding conduction portion 235 and the upper grounding conduction portion 236 come into contact first and can be compressed by the pressing force. Therefore, the first length L1 of the electric power conduction portion and the third length L3 of the grounding conduction portion are decreased, and the first switch gap 218 having the length difference LD1 is reduced.

As the device under test continues to be pressed downward by the pressing force, the second switch gap 228 and the third switch gap 238 are eliminated, and thereafter, the first switch gap 218 having the length difference LD1 is eliminated. Therefore, the electric power conduction portion 220 and the grounding conduction portion 230 are brought into the pressed state, and are brought into the state of being conductive in the up-and-down direction VD. Subsequently, as the electric power conduction portion 220 and the grounding conduction portion 230 are compressed downward, the lower signal conduction portion 215 and the upper signal conduction portion 216 come into contact, and the signal conduction portion 210 is brought into the pressed state and the state of being conductive in the up-and-down direction VD. As such, in the state where the electric power conduction portion 220 and the grounding conduction portion 230 are first compressed and elastically deformed to a predetermined extent and the first switch gap 218 having the length difference LD1 is eliminated, the signal conduction portion 210 is brought into the pressed state. Accordingly, in the pressed state, the signal conduction portion 210 does not have a change in its shape, and the spaced distance between the inner peripheral surface of the first through hole 110 and the outer peripheral surface of the signal conduction portion 210 can be maintained constantly.

Referring to FIG. 14, the lower module 410 and the upper module 420, which are manufactured individually, may be coupled by bonding the first housing 101 and the second housing 102. In the lower module 410, the first housing 101, the lower signal conduction portion 215, the first lower insulation portion 311, the lower electric power conduction portion 225, the second lower insulation portion 321, the lower grounding conduction portion 235, and the third lower insulation portion 331 are formed integrally. In the upper module 420, the second housing 102, the upper signal conduction portion 216, the first upper insulation portion 312, the upper electric power conduction portion 226, the second upper insulation portion 322, the upper grounding conduction portion 236, and the third upper insulation portion 332 are formed integrally. When molding the lower module 410, the lower signal conduction portion 215 is molded so as to have the first switch gap having the above-described length difference. Further, the lower electric power conduction portion 225 and the lower grounding conduction portion 235 are molded so as to have the second switch gap and the third switch gap, respectively. Since the lower module 410 and the upper module 420 are coupled, the connector, in which the first switch gap having the length difference is formed in the signal conduction portion and the second and third switch gaps are formed in the electric power conduction portion and the grounding conduction portion, respectively, can be manufactured. Further, the lower and upper signal conduction portions having a relatively short length are formed in the first and second housings, respectively, and the first and second housings are coupled. Thus, the connector having a minute pitch between the conduction portions can be manufactured.

According to the above-described embodiments, the second length of the signal conduction portion is shorter than the first length by a length difference equal to 5% to 15% of the first length of the electric power conduction portion. Thus, in the pressed state, the signal conduction portion hardly has a shape change, and the spaced distance between the first through hole and the signal conduction portion can be maintained constantly.

To confirm the above-described effects, high frequency tests were conducted on a connector according to a comparative example and a connector according to one embodiment by using simulation software. Reference is made to FIGS. 15 to 18 showing results of the high frequency test simulation.

In graphs shown in FIGS. 15 to 18, a horizontal axis is a frequency of the high frequency, a unit of the frequency is GHz, and a vertical axis has a unit of a decibel (dB). In the graphs shown in FIGS. 15 to 18, a dashed line indicates insertion loss which means a degree of signal loss depending on a frequency band, and a solid line means return loss that indicates a degree of signal reflection. The dashed line related to the insertion loss means that the signal loss does not occur when it is close to 0 dB. Where the solid line related to the return loss is equal to or lower than a reference value (−10 dB), the connector showing such return loss can be used suitably as a connector for high frequency test.

FIG. 15 is a graph showing the result of the high frequency test simulation on the connector according to a comparative example, wherein the second length of the signal conduction portion is shorter than the first length of the electric power conduction portion by a length difference of less than 5% of the first length. According to the graph of FIG. 15, when the connector is pressed with an appropriate stroke, the signal conduction portion is deformed to a considerable extent, and a large return loss occurs thereby. In particular, since the solid line related to the return loss exceeds the reference value (−10 dB) in a frequency band of 35.39 GHz to 71.44 GHz, the connector, in which the second length of the signal conduction portion is shorter than the first length of the electric power conduction portion by the length difference of less than 5% of the first length, exhibits poor signal property during the high frequency test.

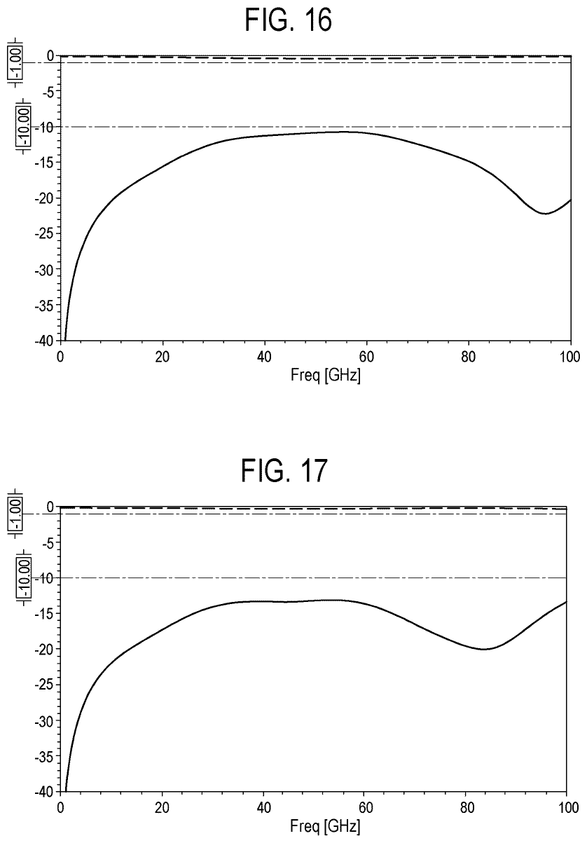

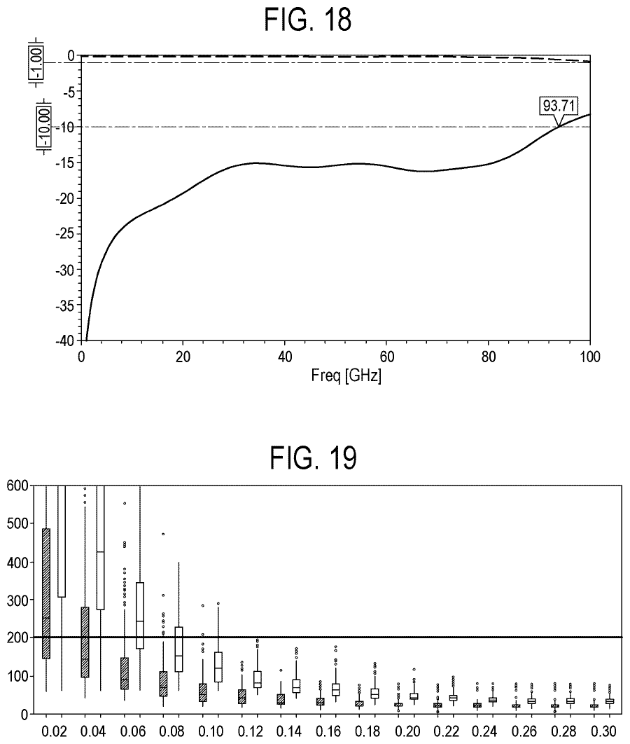

FIGS. 16 to 18 are graphs respectively showing the results of the high frequency test simulation on the connector according to one embodiment. FIG. 16 shows the result of the high frequency test simulation on the connector according to one embodiment, wherein the second length of the signal conduction portion is shorter than the first length of the electric power conduction portion by the length difference of 5% of the first length. FIG. 17 shows the result of the high frequency test simulation on the connector according to one embodiment, wherein the second length of the signal conduction portion is shorter than the first length of the electric power conduction portion by a length difference of 10% of the first length. FIG. 18 shows the result of the high frequency test simulation on the connector according to one embodiment, wherein the second length of the signal conduction portion is shorter than the first length of the electric power conduction portion by a length difference of 15% of the first length. As confirmed from FIGS. 16 to 18, the connector, in which the signal conduction portion has the second length shorter than the first length of the electric power conduction portion by the length difference of 5% to 15% of the first length, exhibits a return loss lower than the reference value (−10 dB) in all the frequency bands. Therefore, the connector according to one embodiment exhibits better signal property in comparison with the connector according to the comparative example.

Further, to confirm the above-described effects, resistance tests were conducted on the connector according to a comparative example and the connector according to one embodiment by using simulation software. Reference is made to FIGS. 19 to 22 which are boxplot charts showing results of the resistance test simulation.

In the boxplot charts shown in FIGS. 19 to 22, a horizontal axis means a stroke that indicates a degree of compression of the connector by the pressing force, and a unit of the stroke is mm. A vertical axis means resistance, and has a unit of mOhm. In FIGS. 19 to 22, a hatched box means the resistance of the electric power conduction portion, and a non-hatched box means the resistance of the signal conduction portion. When the signal conduction portion exhibits a reference resistance of 200 mOhm at a reference stroke of 0.16 mm, the connector having such a signal conduction portion can exhibit good performance as a connector for high frequency test.

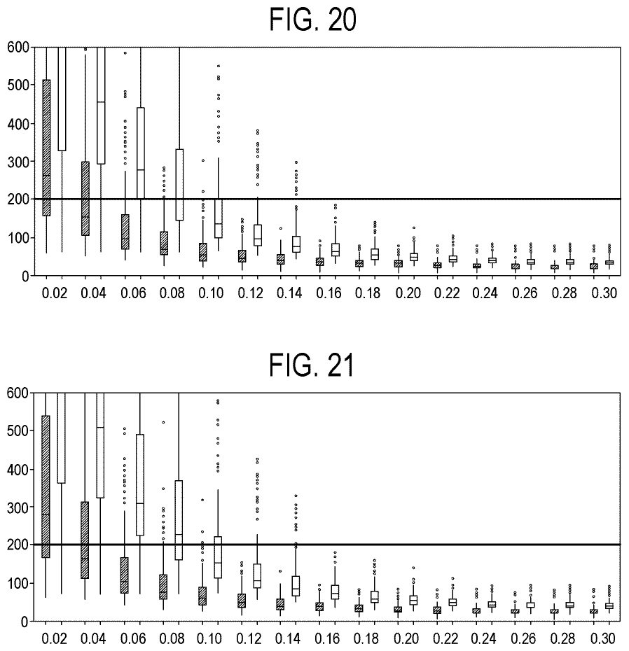

FIG. 19 shows the result of the resistance test simulation on the connector according to one embodiment, wherein the second length of the signal conduction portion is shorter than the first length of the electric power conduction portion by a length difference of 5% of the first length. FIG. 20 shows the result of the resistance test simulation on the connector according to one embodiment, wherein the second length of the signal conduction portion is shorter than the first length of the electric power conduction portion by a length difference of 10% of the first length. FIG. 21 shows the result of the resistance test simulation on the connector according to one embodiment, wherein the second length of the signal conduction portion is shorter than the first length of the electric power conduction portion by a length difference of 15% of the first length. As confirmed from FIGS. 19 to 21, where the signal conduction portion has the second length shorter than the first length of the electric power conduction portion by the length difference of 5% to 15% of the first length, the signal conduction portion exhibits a resistance value less than 200 mOhm at the reference stroke of 0.16 mm.

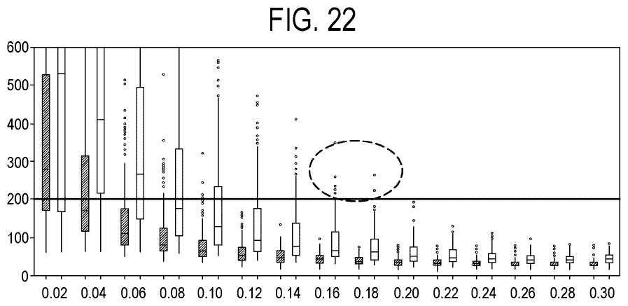

FIG. 22 shows the result of the resistance test simulation on the connector according to a comparative example, wherein the second length of the signal conduction portion is shorter than the first length of the electric power conduction portion by a length difference of 20% of the first length. As confirmed from a dashed-lined circle of FIG. 22, where the length difference is equal to or more than 20%, the connector according to a comparative example shows a resistance value exceeding 200 mOhm at the reference stroke of 0.16 mm. Therefore, the connector according to a comparative example exhibits poor performance as a connector for high frequency test.

The technical idea of the present disclosure has been described heretofore with reference to some embodiments and examples shown in the accompanying drawings. However, it is to be understood that various substitutions, modifications, and alterations may be made without departing from the technical idea and scope of the present disclosure that can be understood by those of ordinary skill in the technical field to which the present disclosure pertains. Further, it is to be understood that such substitutions, modifications, and alterations fall within the scope of the appended claims.

What is claimed is:

1. A testing connector disposed between a test apparatus and a device under test, comprising:
an electric power conduction portion; and
a signal conduction portion,
wherein the electric power conduction portion has a first length, which is a distance from a lower end of the electric power conduction portion to an upper end of the electric power conduction portion in a non-pressed state,
wherein the signal conduction portion has a second length, which is a distance from a lower end of the signal conduction portion to an upper end of the signal conduction portion in the non-pressed state, and
wherein the second length is shorter than the first length.

2. The testing connector of claim 1, wherein, when a pressing force is applied to the testing connector, the electric power conduction portion is compressed before the signal conduction portion is compressed.

3. The testing connector of claim 1, wherein, in the non-pressed state, the second length is shorter than the first length by a length difference equal to 5% to 15% of the first length.

4. The testing connector of claim 3, wherein the length difference is defined by a height difference between the upper end of the electric power conduction portion and the upper end of the signal conduction portion.

5. The testing connector of claim 3, wherein the length difference is defined by a height difference between the lower end of the electric power conduction portion and the lower end of the signal conduction portion.

6. The testing connector of claim 3, wherein the signal conduction portion includes an upper signal conduction portion and a lower signal conduction portion, which are separated from each other and are spaced apart, and
wherein the length difference is defined by a spaced distance between the upper signal conduction portion and the lower signal conduction portion.

7. The testing connector of claim 3, wherein the electric power conduction portion includes a protruding conduction portion, which protrudes more upward than the upper end of the signal conduction portion and has a length corresponding to the length difference, and wherein an upper end of the protruding conduction portion forms the upper end of the electric power conduction portion.

8. The testing connector of claim 1, wherein, in the non-pressed state, the upper end of the signal conduction portion is positioned below the upper end of the electric power conduction portion.

9. The testing connector of claim 1, wherein, in the non-pressed state, the lower end of the signal conduction portion is positioned above the lower end of the electric power conduction portion.

10. The testing connector of claim 1, further comprising a grounding conduction portion,
wherein the grounding conduction portion has a third length, which is a length from a lower end of the grounding conduction portion to an upper end of the grounding conduction portion, and
wherein the second length is shorter than the third length.

11. The testing connector of claim 1, further comprising:
a housing having a first through hole, in which the signal conduction portion is disposed and which is perforated through in an up-and-down direction, and a second through hole, in which the electric power conduction portion is disposed and which is perforated through in the up-and-down direction;
a first insulation portion disposed in the first through hole, insulating the signal conduction portion from the housing, and positioning the signal conduction portion coaxially with a central axis of the first through hole; and
a second insulation portion disposed in the second through hole and insulating the electric power conduction portion from the housing.

12. The testing connector of claim 11, wherein the first insulation portion includes a first lower insulation portion and a first upper insulation portion, which are disposed at a lower side and an upper side of the first through hole, respectively, and
wherein an inner peripheral surface of the first through hole, an upper surface of the first lower insulation portion, and a lower surface of the first upper insulation portion form an insulation space surrounding an outer peripheral surface of the signal conduction portion.

13. The testing connector of claim 11, wherein the housing includes:
a first housing having first and second lower through holes forming the first and second through holes, respectively; and
a second housing having first and second upper through holes forming the first and second through holes, respectively, and disposed on the first housing,
wherein the first insulation portion includes a first lower insulation portion and a first upper insulation portion, which are disposed in the first lower through hole and the first upper through hole, respectively, and
wherein the second insulation portion includes a second lower insulation portion and a second upper insulation portion, which are disposed in the second lower through hole and the second upper through hole, respectively.

14. The testing connector of claim 13, wherein, by the signal conduction portion and the electric power conduction portion, the second housing is spaced apart from the first housing and is supported with respect to the first housing.

15. The testing connector of claim 13, wherein the signal conduction portion includes:
a lower signal conduction portion coupled to the first lower insulation portion; and
an upper signal conduction portion coupled to the first upper insulation portion, spaced apart upward from the lower signal conduction portion by a switch gap in the non-pressed state, and conductively coming in contact with the lower signal conduction portion in a pressed state, and
wherein, in the non-pressed state, an up-and-down directional length of the switch gap is equal to a length difference of the first length and the second length.

16. The testing connector of claim 15, wherein the lower signal conduction portion and the upper signal conduction portion have different diameters from each other.

17. The testing connector of claim 13, wherein the electric power conduction portion is coupled to the second upper insulation portion and is insertable into the second lower insulation portion.

18. The testing connector of claim 13, wherein the housing further includes an elastic insulation housing, which is disposed between the first housing and the second housing and has insertion holes becoming a portion of the first upper through hole and the second upper through hole.

19. The testing connector of claim 13, wherein the signal conduction portion includes:
a lower signal conduction portion coupled to the first lower insulation portion; and
an upper signal conduction portion coupled to the first upper insulation portion, spaced apart upward from the lower signal conduction portion by a first switch gap in the non-pressed state, and conductively coming in contact with the lower signal conduction portion in a pressed state,
wherein the electric power conduction portion includes:
a lower electric power conduction portion coupled to the second lower insulation portion; and
an upper electric power conduction portion coupled to the second upper insulation portion, spaced apart upward from the lower electric power conduction portion by a second switch gap in the non-pressed state, and conductively coming in contact with the lower electric power conduction portion in the pressed state, and
wherein, in the non-pressed state, a length of the first switch gap in the up-and-down direction is a sum of a length of the second switch gap in the up-and-down direction and a length difference of the first length and the second length.

20. The testing connector of claim 11, further comprising:
a grounding conduction portion disposed in the up-and-down direction in a third through hole of the housing perforated through in the up-and-down direction; and
a third insulation portion disposed in the third through hole,
wherein, in the non-pressed state, the grounding conduction portion has a third length, which is a distance between a lower end and an upper end of the grounding conduction portion and is longer than the second length.

21. The testing connector of claim 20, wherein, in the non-pressed state, the upper end of the signal conduction portion is positioned below the upper end of the grounding conduction portion.

22. The testing connector of claim 20, wherein, in the non-pressed state, the lower end of the signal conduction portion is positioned above the lower end of the grounding conduction portion.

23. The testing connector of claim 20, wherein the electric power conduction portion and the grounding conduction portion have a diameter greater than a diameter of the signal conduction portion.
